(19) United States
(12) Patent Application Publication
(10) Pub. No.: US 2025/0336809 A1
(43) Pub. Date: Oct. 30, 2025

(54) STACKED MULTI-GATE DEVICE WITH FRONT-AND-BACK INTERCONNECTION AND METHODS FOR FORMING THE SAME

(71) Applicant: Taiwan Semiconductor Manufacturing Co., Ltd., Hsinchu (TW)

(72) Inventors: Wei-Xiang You, Kaohsiung City (TW); Jui-Chien Huang, Hsinchu (TW); Chun-Yen Lin, Hsinchu (TW); Szuya Liao, Zhubei (TW)

(21) Appl. No.: 19/262,721

(22) Filed: Jul. 8, 2025

Related U.S. Application Data
(63) Continuation of application No. 18/482,190, filed on Oct. 6, 2023.

(51) Int. Cl. H01L 23/522; H01L 23/528; H10D 30/01; H10D 30/43; H10D 30/67; H10D 62/10; H10D 64/01; H10D 84/01; H10D 84/03; H10D 84/85

(52) U.S. Cl. CPC H01L 23/5226; H01L 23/5283; H10D 30/014; H10D 30/43; H10D 30/6735; H10D 30/6757; H10D 62/121; H10D 64/017; H10D 64/021; H10D 84/0167; H10D 84/038; H10D 84/85

(57) ABSTRACT

A method includes forming a first CFET and a second CFET. The first CFET includes a first lower transistor, and a first upper transistor overlapping the first lower transistor. The second CFET includes a second lower transistor, and a second upper transistor overlapping the second lower transistor. The method further includes performing a first etching process to form a first opening, wherein the first etching process includes etching a first gate stack between the first upper transistor and the second upper transistor, and etching a second gate stack between the first lower transistor and the second lower transistor. The first opening is filled with a dielectric material to form a dielectric region. The method further includes performing a second etching process to etch a middle portion of the dielectric region and to form a second opening, and filling the second opening with a conductive material to form a through-via.

### CROSS-REFERENCE TO RELATED APPLICATIONS

This application is a continuation of U.S. patent application Ser. No. 18/482,190, filed on Oct. 6, 2023 and entitled “Stacked Multi-Gate Device with Front-and-Back Interconnection and Methods for Forming the Same,” which application is hereby incorporated herein by reference.

### BACKGROUND

Complementary Field-Effect Transistors (CFETs) are being developed to meet the increasing demanding requirement for increasing the density of transistors in integrated circuits. A CFET includes a lower transistor and an upper transistor overlapping the lower transistor. The lower transistors and upper transistors of multiple CFETs may be interconnected to form circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a Complementary Field-Effect Transistor (CFET) and a through-via in accordance with some embodiments.

FIGS. 2-7, 8A, 8B, 9A, 9B, 10A, 10B, 11A, 11B, and 12-13 illustrate the views in the formation of CFETs and a through-via in a monolithic CFET formation process in accordance with some embodiments.

FIG. 14 illustrates a through-via laterally extending to source/drain regions of CFETs in accordance with some embodiments.

FIGS. 15, 16A, and 16B illustrate the views in the backside formation of a through-via in accordance with some embodiments.

FIGS. 17-19, 20A, and 20B illustrate the views in the formation of a through-via from both of front side and backside of a respective wafer in accordance with some embodiments.

FIGS. 21-31 illustrate the views in the formation of CFETs and a through-via in a parallel CFET formation process in accordance with some embodiments.

FIGS. 32-39 illustrate the views in the formation of CFETs and a through-via in a sequential CFET formation process in accordance with some embodiments.

FIG. 40 illustrates a through-via formed through both of front-side formation process and backside formation process in a sequential formation process in accordance with some embodiments.

FIG. 41 illustrates a process flow for forming a through-via in CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs) and a through-via used for front-and-back interconnection and the method of forming the same are provided. In accordance with some embodiments, a dielectric region is formed, which is sometimes referred to as a single diffusion break (SDB) region or a cut poly on diffusion edge region. The SDB region is etched to form an opening therein, followed by filling the opening to form a through-via, which may be formed of metal. The through-via extends from the top surface level of top FETs to the bottom level of the bottom FETs, and may be used for the electrical and signal interconnection between the front side and the backside of the respective wafer. The Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

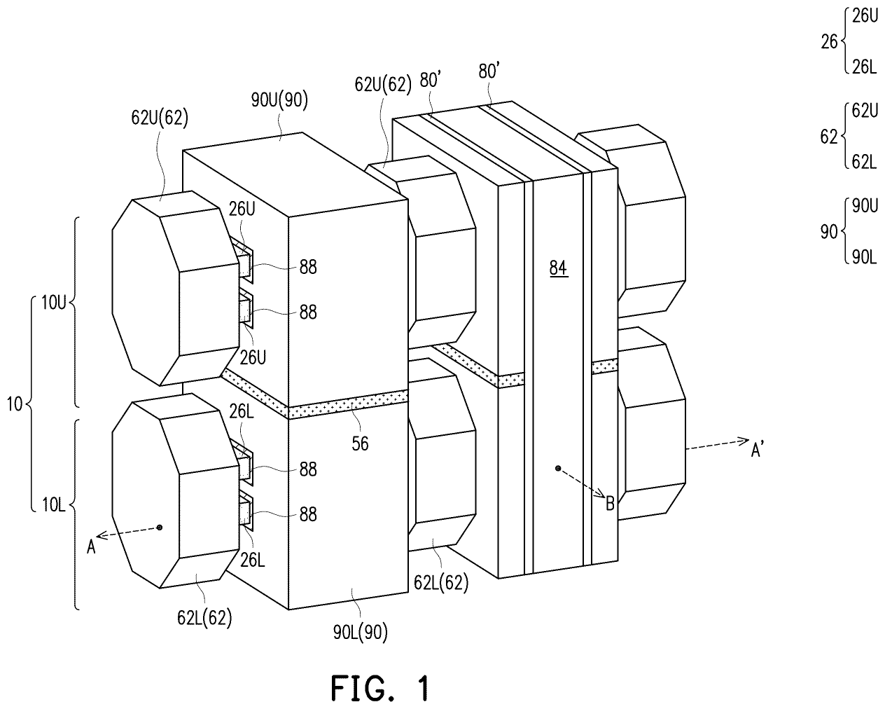

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity. The CFETs include multiple vertically stacked FETs. For example, a CFET may include a lower nanostructure-FET (transistor) 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26 (including lower semiconductor nanostructures 26L and upper semiconductor nanostructures 26U), wherein the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U.

Gate dielectrics 88 encircle the respective semiconductor nanostructures 26. Gate electrodes 90 (including a lower gate electrode 90L and an upper gate electrode 90U) are formed on the gate dielectrics 88. Source/drain regions 62 (including lower source/drain regions 62L and upper source/drain regions 62U) are disposed on opposing sides of the gate dielectrics 88 and the respective gate electrodes 90. The source/drain region may refer to a source or a drain, individually or collectively dependent upon the context. Isolation features (not shown) may be formed to separate desired ones of the source/drain regions 62 and/or desired ones of the gate electrodes 90. FIG. 1 further illustrates through-via 84, which is formed inside dielectric liner 80′. Through-via 84 is electrically conductive, and may be formed of a metal or a metal alloy. Dielectric liner 80′ may be an outer portion of an etched SDB region.

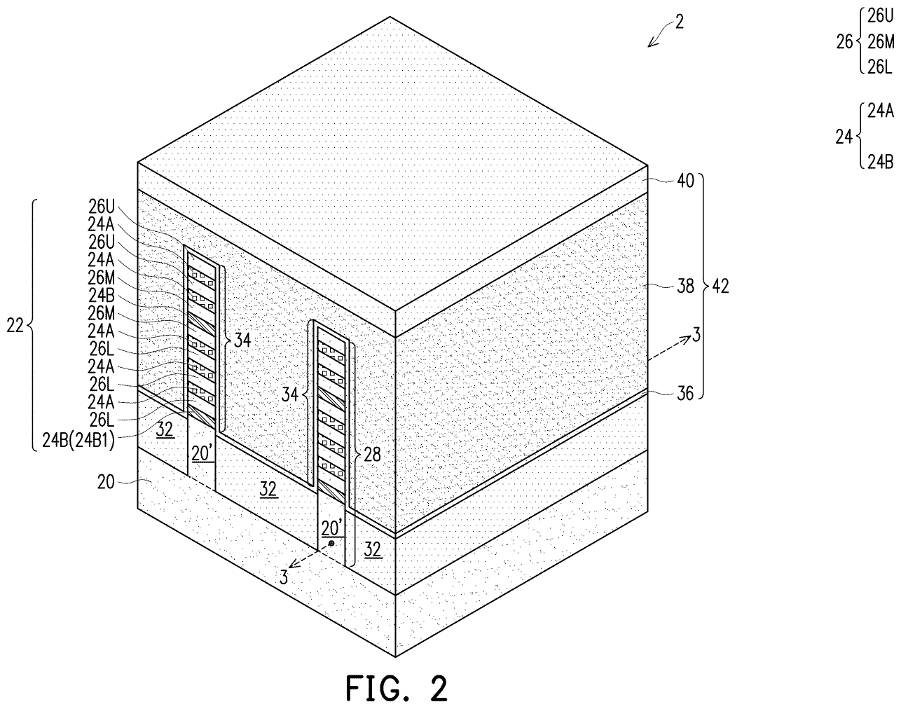

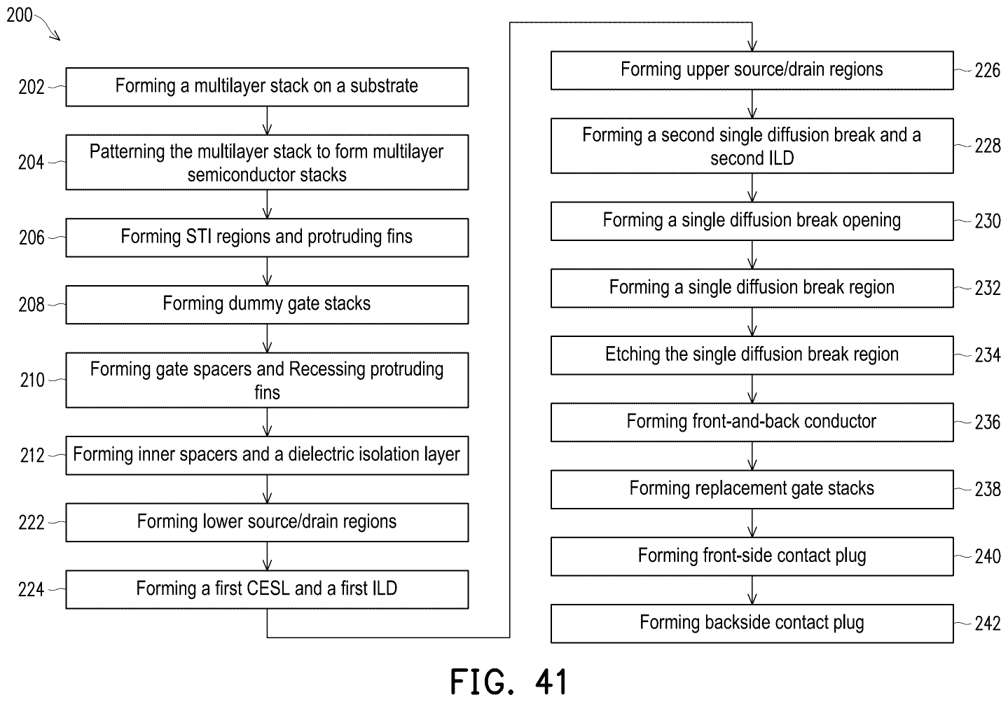

FIGS. 2-7, 8A, 8B, 9A, 9B, 10A, 10B, 11A, 11B, and 12-13 illustrate the cross-sectional views of intermediate stages in the formation of CFETs and a through-via using SDB processes in accordance with some embodiments of the present disclosure. The corresponding processes are also reflected schematically in the process flow 200 as shown in FIG. 41. The formation of the CFETs according to these figures is referred to as a monolithic formation process since the formation of the upper FETs and lower FETs may share a plurality of common formation processes. In subsequent discussion, unless specified otherwise, the figures having digits followed by letter “A” may illustrate the vertical cross-sectional views along a similar cross-section as vertical reference cross-section A-A′ in FIG. 1. The figures having digits followed by letter “B” may illustrate the cross-sectional views along a similar cross-section as the vertical reference cross-section B-B′in FIG. 1.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. In accordance with some embodiments, the semiconductor material of the substrate 20 may include silicon, germanium, carbon-doped silicon, a III-V compound semiconductor; or the like, or combinations thereof.

A multi-layer stack 22 is formed over the substrate 20. The respective process is illustrated as process 202 in the process flow 200 as shown in FIG. 41. The multi-layer stack 22 includes alternating dummy semiconductor layers 24 and semiconductor layers 26. Dummy semiconductor layers 24 include dummy semiconductor layers 24A and dummy semiconductor layer 24B. Semiconductor layers 26 include lower semiconductor nanostructures 26L and upper semiconductor nanostructures 26U. Lower semiconductor nanostructures 26L and upper semiconductor nanostructures 26U are for forming a lower FET and an upper FET, respectively.

In accordance with some embodiments, there is a bottom dummy semiconductor layer 24B (marked as 24B1 for distinction) over and physically contacting semiconductor strip 20′, which is a portion of substrate 20. In accordance with alternative embodiments, the bottom dummy semiconductor layers 24B are not formed, and semiconductor strip 20′ may be in physical contact with the respective overlying dummy semiconductor layer 24A. Accordingly, the bottom dummy semiconductor layers 24B1 are shown as being dashed in subsequent figures to indicate that these layers may or may not exist.

Appropriate well regions (not separately illustrated) such as p-well regions and n-well regions may be formed in lower semiconductor nanostructures 26L and upper semiconductor nanostructures 26U. For example, semiconductor nanostructures 26L and 26U may be in-situ doped (when epitaxially grown) and/or implanted to desirable conductivity types.

The dummy semiconductor layers 24A are formed of a first semiconductor material, the dummy semiconductor layer(s) 24B are formed of a second semiconductor material different from the first semiconductor material. The first and second semiconductor materials may be selected from the same group of candidate semiconductor materials of the substrate 20. The first and second semiconductor materials have a high etching selectivity to one another. As such, the dummy semiconductor layer(s) 24B may be removed at a faster rate than the dummy semiconductor layers 24A in subsequent processes.

The semiconductor layers 26 (including the lower semiconductor nanostructures 26L and upper semiconductor nanostructures 26U) are formed of one or more semiconductor material(s). The semiconductor material(s) may also be selected from the same group of candidate semiconductor materials of the substrate 20. The lower semiconductor nanostructures 26L and the upper semiconductor nanostructures 26U may be formed of the same semiconductor material, or may be formed of different semiconductor materials.

In accordance with some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than dummy semiconductor layers 24A.

Multi-layer stack 22 and substrate 20 are patterned to form semiconductor strips 28. The respective process is illustrated as process 204 in the process flow 200 as shown in FIG. 41. Each of semiconductor strips 28 includes semiconductor strip 20′ (the portions of the original substrate 20) and multi-multi-layer stack 22′, which is the remaining portion of multi-layer stack 22. The layers in the remaining portions 22′ may be referred to as nanostructures hereinafter. The etching may be performed by any acceptable etch process, such as a Reactive Ion Etch (RIE), Neutral Beam Etch (NBE), the like, or a combination thereof. The etching may be anisotropic. Dummy semiconductor layers 24A and dummy nanostructures 24B may further be collectively referred to as dummy nanostructures 24.

The lower semiconductor nanostructures 26L will act as channel regions for lower nanostructure-FETs of the CFETs. The upper semiconductor nanostructures 26U will act as channel regions for upper nanostructure-FETs of the CFETs. The middle semiconductor nanostructures 26M are the semiconductor nanostructures 26 that are immediately above/below (e.g., in contact with) the dummy nanostructures 24B. The middle semiconductor nanostructures 26M may be used for isolation and may or may not act as channel regions for the CFETs. The dummy nanostructures 24B will be subsequently replaced with dielectric isolation structures. The dielectric isolation structures and the middle semiconductor nanostructures 26M may define boundaries of the lower nanostructure-FETs and the upper nanostructure-FETs.

Isolation regions 32 are formed over the substrate 20 and between adjacent semiconductor strips 28. The respective process is illustrated as process 206 in the process flow 200 as shown in FIG. 41. Isolation regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of isolation regions 32 may include depositing the dielectric layer(s), and performing a planarization process such as a Chemical Mechanical Polish (CMP) process, a mechanical polishing process, or the like to remove excess portions of the dielectric materials. The deposition processes may include chemical vapor deposition (CVD), atomic layer deposition (ALD), HDP-CVD, FCVD, the like, or a combination thereof. In accordance with some embodiments, the isolation regions 32 include silicon oxide formed by an FCVD process, followed by an anneal process.

After the planarization process, isolation regions 32 are recessed. Some upper portions of semiconductor strips 28 (including multi-layer stacks 22′) protrude higher than the remaining isolation regions 32 to form protruding fins 34. The respective process is also illustrated as process 206 in the process flow 200 as shown in FIG. 41.

Dummy gate dielectric 36 is formed on the protruding fins 34. Dummy gate dielectric 36 may be formed of or comprise, for example, silicon oxide, silicon nitride, a combination thereof, or the like, and may be deposited or thermally grown according to acceptable techniques. A dummy gate layer 38 is formed over the dummy gate dielectric 36. The dummy gate layer 38 may be deposited, for example, through Physical Vapor Deposition (PVD), CVD, or other techniques, and then planarized, such as by a CMP process. The material of dummy gate layer 38 may be conductive or non-conductive, and may be selected from a group including amorphous silicon, polycrystalline-silicon (polysilicon), poly-crystalline silicon-germanium (poly-SiGe), or the like. One or more mask layer(s) 40 is formed over the planarized dummy gate layer 38, and may include, for example, silicon nitride, silicon oxynitride, or the like.

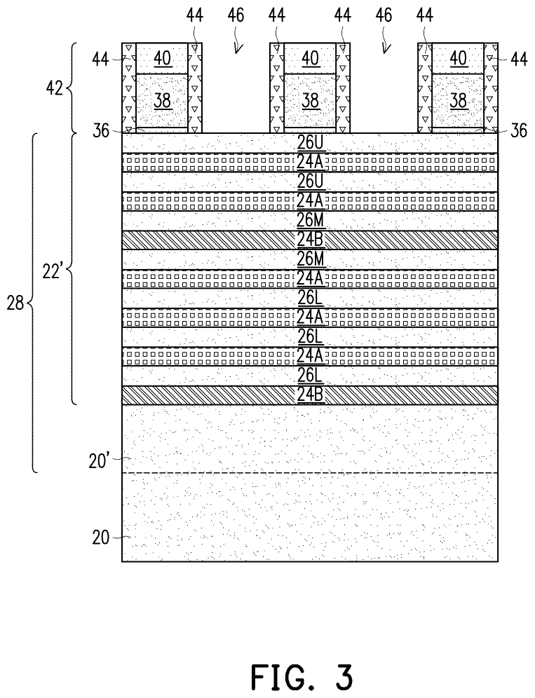

Next, the mask layer 40 may be patterned through photolithography and etching processes to form a mask, which is then used to etch and pattern dummy gate layer 38, and possibly dummy gate dielectric 36. A resulting structure is shown in FIG. 3, which illustrates a vertical cross-section 3-3 in FIG. 2, which cross-section is along the lengthwise direction of semiconductor strip 28. The remaining portions of mask layer 40, dummy gate layer 38, and dummy gate dielectric 36 form dummy gate stacks 42 as shown in FIG. 3. The respective process is illustrated as process 208 in the process flow 200 as shown in FIG. 41.

Gate spacers 44 are then formed over the multi-layer stacks 22′ and on the exposed sidewalls of dummy gate stacks 42. The respective process is illustrated as process 210 in the process flow 200 as shown in FIG. 41. The gate spacers 44 may be formed by conformally depositing one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

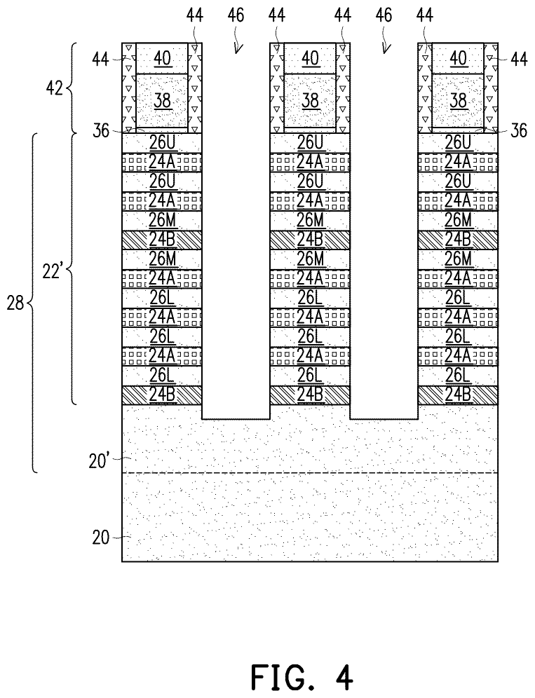

Referring to FIG. 4, source/drain recesses 46 are formed in semiconductor strips 28. The respective process is also illustrated as process 210 in the process flow 200 as shown in FIG. 41. The source/drain recesses 46 are formed through etching, and may extend through the multi-layer stacks 22′ and into the semiconductor strips 20′. The bottom surfaces of the source/drain recesses 46 may be at a level above, below, or level with the top surfaces of the isolation regions 32 (not shown in FIG. 4). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

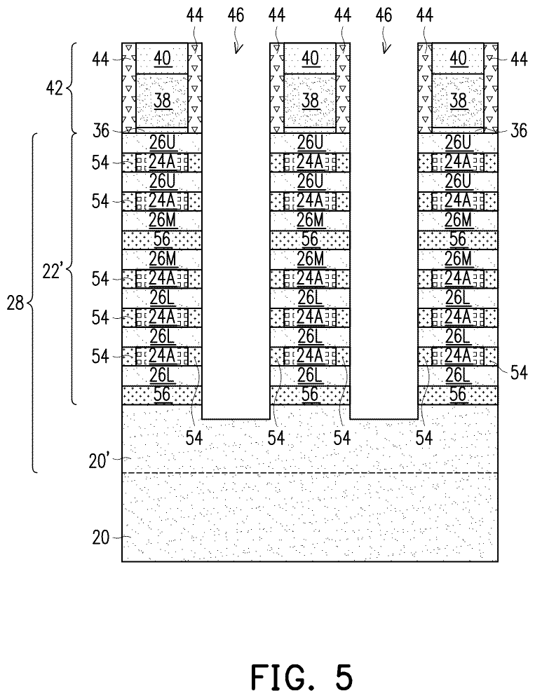

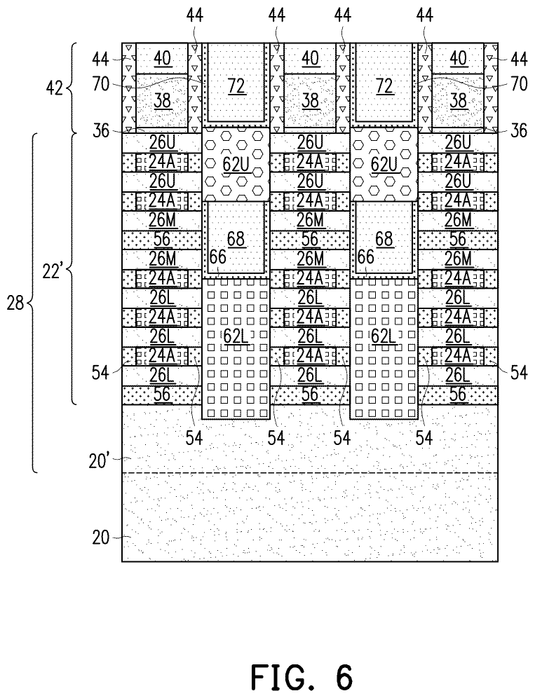

In FIG. 5, inner spacers 54 and dielectric isolation layers 56 are formed. The respective process is illustrated as process 212 in the process flow 200 as shown in FIG. 41. The formation of inner spacers 54 and dielectric isolation layers 56 may include an etching process that laterally etches the dummy semiconductor layers 24A and removes the dummy nanostructure 24B (FIG. 6).

The etching process may be isotropic and may be selective to the material of the dummy semiconductor layers 24A, so that the dummy semiconductor layers 24A are etched at a faster rate than the semiconductor nanostructures 26U and 26L. The etching process may also be selective to the material of the dummy nanostructures 24B, so that the dummy nanostructures 24B are etched at a faster rate than the dummy semiconductor layers 24A. In this manner, the dummy nanostructures 24B may be completely removed, while the dummy semiconductor layers 24A are laterally recessed.

In accordance with some embodiments in which the dummy nanostructures 24B are formed of germanium or silicon germanium with a high germanium atomic percentage, the dummy semiconductor layers 24A are formed of silicon germanium with a low germanium atomic percentage, and the semiconductor nanostructures 26 (including 26M, 26U and 26L) are formed of silicon free from germanium, the etch process may comprise a dry etch process using chlorine gas, with or without a plasma.

Because the dummy gate stacks 42 are in contact with the sidewalls of the semiconductor nanostructures 26 (see FIG. 2), the dummy gate stacks 42 may support the upper semiconductor nanostructures 26U so that the upper semiconductor nanostructures 26U do not collapse upon the removal of the dummy nanostructures 24B. Further, although the sidewalls of the dummy semiconductor layers 24A are illustrated as being straight after the etching, the sidewalls may be concave or convex.

Inner spacers 54 are formed on sidewalls of the laterally recessed dummy semiconductor layers 24A, and dielectric isolation layers 56 are formed between the upper semiconductor nanostructures 26U (collectively) and the lower semiconductor nanostructures 26L (collectively). In the subsequent formation of source/drain regions, the inner spacers 54 may act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Furthermore, middle semiconductor nanostructures 26M and dielectric isolation layers 56 may define the boundaries of the lower nanostructure-FETs and the upper nanostructure-FETs.

The inner spacers 54 and the dielectric isolation layers 56 may be formed by conformally depositing a dielectric insulating material in the source/drain recesses 46, and between the upper and lower semiconductor nanostructures 26U and 26L, and then etching the insulating material. The insulating material may be a non-low-k dielectric material, which may be a carbon-containing dielectric material such as silicon oxycarbonitride, silicon oxycarbide, silicon oxynitride, or the like. The insulating material may be formed by a deposition process, such as ALD, CVD, or the like. The etching of the insulating material may be anisotropic or isotropic. The insulating material, after being etched, has portions remaining on the sidewalls of the dummy semiconductor layers 24A (thus forming the inner spacers 54) and has portions remaining between the upper and lower semiconductor nanostructures 26U and 26L (thus forming the dielectric isolation layers 56).

Referring to FIG. 6, lower epitaxial source/drain regions 62L are formed. The lower epitaxial source/drain regions 62L are formed in the lower portions of the source/drain recesses 46. The respective process is illustrated as process 222 in the process flow 200 as shown in FIG. 41. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy semiconductor layers 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like.

The lower epitaxial source/drain regions 62L may be in-situ doped, and may be, or may not be, implanted with the corresponding p-type or n-type dopants. During the epitaxy of the lower epitaxial source/drain regions 62L, the upper semiconductor nanostructures 26U may be masked to prevent undesired epitaxial growth on the upper semiconductor nanostructures 26U. After the lower epitaxial source/drain regions 62L are grown, the masks on the upper semiconductor nanostructures 26U are removed.

A first Contact Etch Stop Layer (CESL) 66 and a first Inter-Layer Dielectric (ILD) 68 are formed over the lower epitaxial source/drain regions 62L. The respective process is illustrated as process 224 in the process flow 200 as shown in FIG. 41. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In accordance with some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The respective process is illustrated as process 226 in the process flow 200 as shown in FIG. 41. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. For example, the upper epitaxial source/drain regions 62U may be oppositely doped than the lower epitaxial source/drain regions 62L. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The respective process is illustrated as process 228 in the process flow 200 as shown in FIG. 41. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

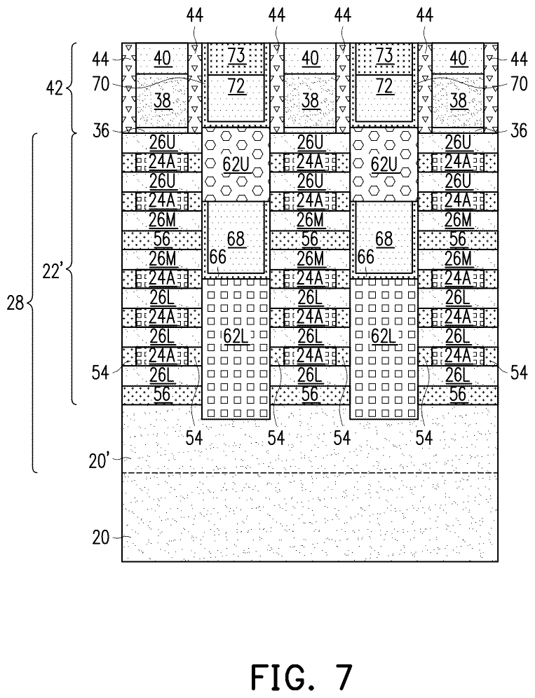

Referring to FIG. 7, hard masks 73 are formed on top of ILD 72. The formation process may include recessing ILD 72 to form recesses, filling the recesses with a dielectric material such as silicon nitride, silicon oxynitride, silicon oxy carbo nitride, or the like. A planarization process is then performed to remove excess portions of the dielectric material, leaving behind hard masks 73.

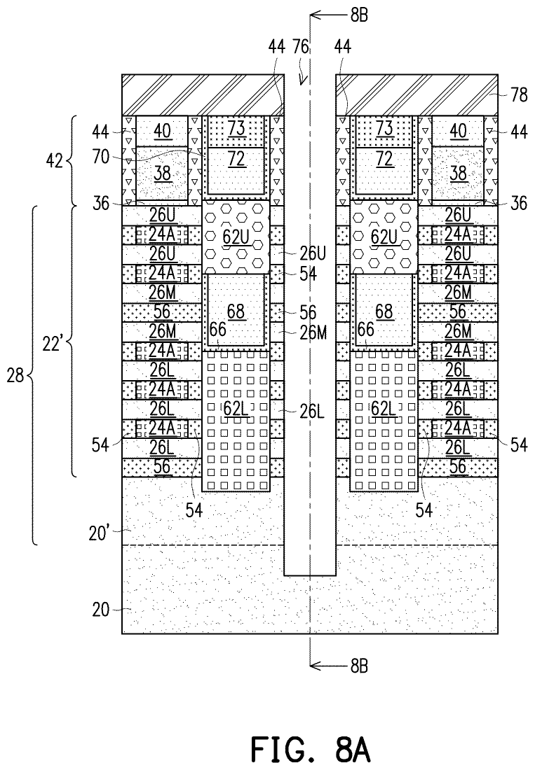

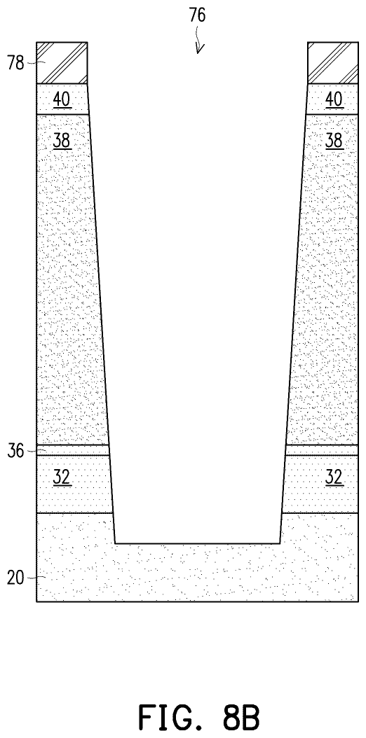

FIGS. 8A and 8B through FIG. 12 illustrate the formation of through-via 84 from the front side of the respective wafer in accordance with some embodiments. In FIGS. 8A and 8B, a trench 76 (also referred to as an opening) is formed between two of the adjacent source/drain regions 62 (including 62U and 62L). Trench 76 is alternatively referred to as a SDB opening. The respective process is illustrated as process 230 in the process flow 200 as shown in FIG. 41. FIG. 8B illustrates the cross-section 8B-8B in FIG. 8A. The trench 76 is formed by etching a portion of the dummy gate stack 42, as well as the underlying portion of multi-layer stack 22′. Some portions of the multi-layer stack 22′ are active regions. Trench 76 extends into, and may penetrate through, semiconductor strips 20′.

To form trench 76, etching mask 78 (which may comprise a patterned photoresist) is formed over the structure of FIGS. 8A and 8B. The etching mask 78 is patterned and the pattern is then transferred to the underlying structures by an etching process(es) to remove the underlying materials and form the trench 76. The etching may include a plurality of etch processes for etching different materials.

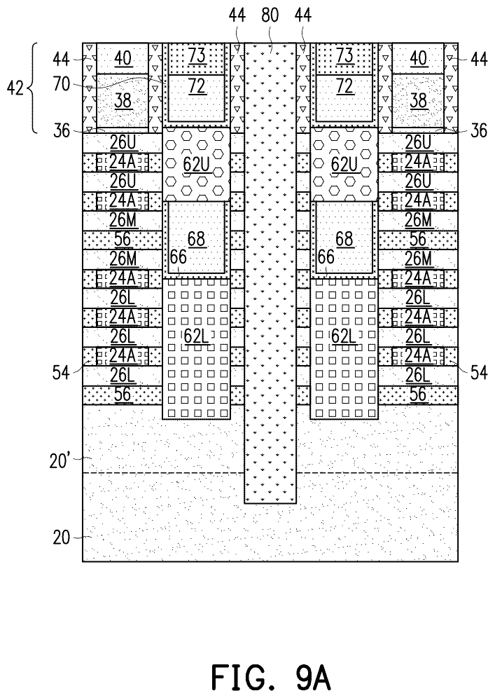

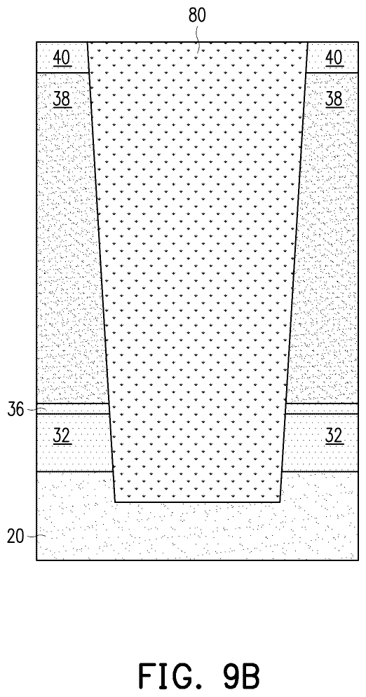

Trench 76 is then filled with a dielectric material to form dielectric region 80. The resulting structure is shown in FIGS. 9A and 9B. The process of etching dummy gate stacks and the underlying active regions, and then forming the dielectric region 80 is also referred to as an SDB process. Accordingly, dielectric region 80 may also be referred to as an SDB region. The respective process is illustrated as process 232 in the process flow 200 as shown in FIG. 41. The dielectric material may include silicon oxide, silicon nitride, silicon oxynitride, silicon oxycarbonitride, boron nitride, combinations thereof, multi-layers thereof, or the like. The respective deposition process may be conformal or non-conformal, and may include CVD, ALD, PECVD, Flowable Chemical Vapor Deposition (FCVD), or the like.

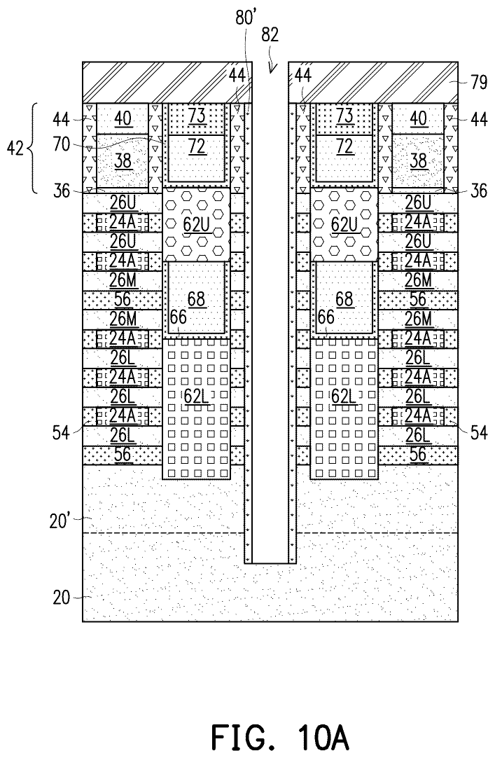

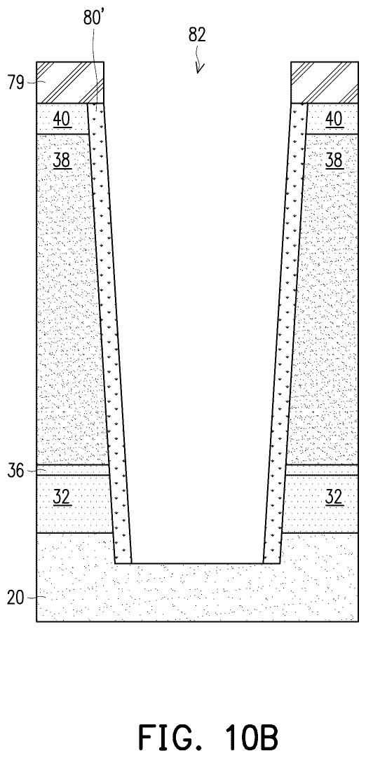

Referring to FIGS. 10A and 10B, dielectric region 80 is etched to remove a middle portion, leaving behind outer portions that form a ring, which is referred to as dielectric liner 80′. The respective process is illustrated as process 234 in the process flow 200 as shown in FIG. 41. Trench 82 (also referred to as an opening) is thus formed, with dielectric liner 80′ forming a full ring encircling trench 82 when viewed from top. Dielectric liner 80′ has no break therein, so that it may effectively isolation the subsequently formed through-via 84 from semiconductor nanostructures 26U and 26L. To form trench 82, etching mask 79 may be formed and patterned, and is used to etch away the middle portion of dielectric region 80.

In accordance with some embodiments, the dielectric liner 80′ has a sidewall thickness in the range between about 1 and 3 nm. It is appreciated that dielectric liner 80′ cannot be too thick or too thin. If the dielectric liner 80′ has a thickness too small, such as less than 1 nm, there is a risk that a subsequently deposited conductive filling material can short to a gate electrode, a semiconductor nanostructure, or source/drain region or that an additional leakage path may be created. If the dielectric liner 80′ has a sidewall thickness that is too large, for example, above 3 nm, in subsequent processes, it is difficult to fill conductive filling material into trench 82 due to the high aspect ratio, and voids may be generated in the resulting through-via. The voids in the through-via cause the adverse increase in the resistance of the through-via.

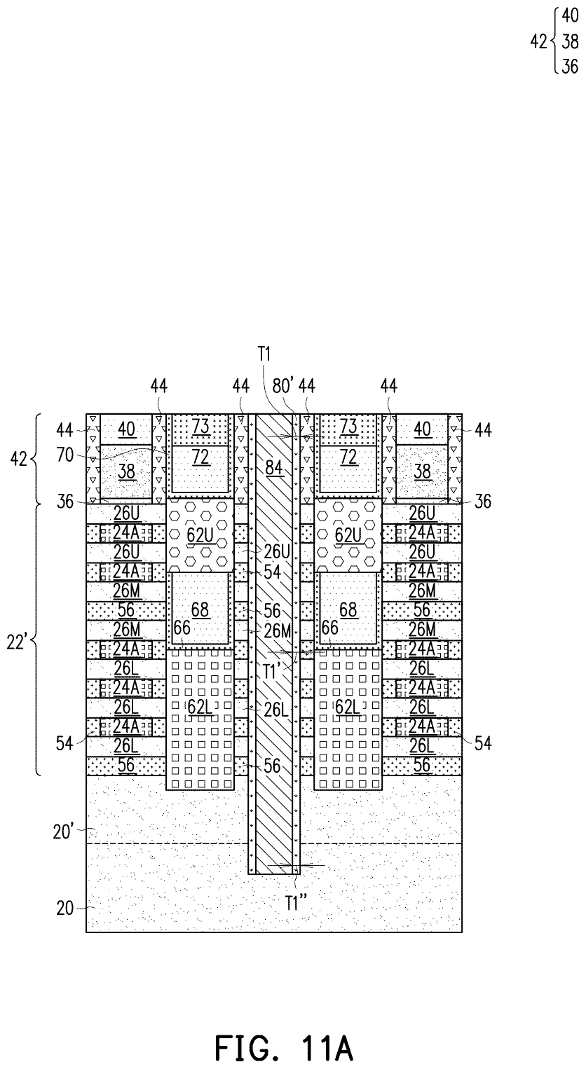

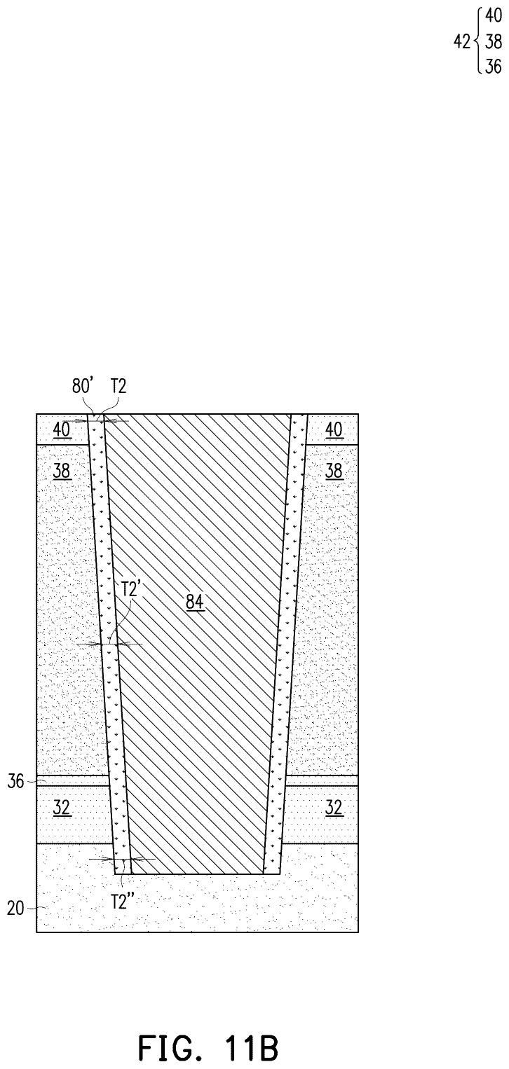

In FIGS. 11A and 11B, a conductive filling material is deposited in the trench, followed by a planarization process to level the top surface of the conductive filling material with the top surface of the masks 73 (if present, or dummy gate electrode 38). Through-via 84 is thus formed between adjacent source/drain regions of two neighboring CFETs. The respective process is illustrated as process 236 in the process flow 200 as shown in FIG. 41. The conductive filling material may be formed of or comprise cobalt, tungsten, ruthenium, copper, molybdenum, the like, or alloys thereof. The conductive filling material may be deposited by any suitable process, such as physical vapor deposition (PVD), CVD, ALD, metal organic chemical vapor deposition (MOCVD), or the like.

The resulting through-via 84 may not be too wide or too narrow. If the conductive filling material is too narrow, the high aspect ratio can cause voids in the deposition process and result in through-via 84 to have a too-high resistance. If the conductive filling material is too wide, it can encroach on adjacent conductive structures, such as a subsequently formed gate electrode or the source/drain regions, and a risk of a short or an additional leakage path is created. In accordance with some embodiments, the resulting through-via 84 may have a width (from sidewall to sidewall) in the range between about 8 nm and 12 nm.

In accordance with some embodiments, as shown in FIG. 11A, the sidewalls of dielectric liner 80′ are in contact with the sidewalls of inner spacers 54 and nanostructures 26U and 26L, and may be in contact with the sidewalls of gate spacers 44. The width of the structure including dielectric liner 80′ and through-via 84 may be the same (within process variation) of the width of dummy gate stacks 42, or may be slightly greater than the width of dummy gate stacks 42 due to the consumption of gate spacers 44 in the etching processes. In accordance with these embodiments, gate spacers 44 are on opposing sides of and contacting dielectric liner 80′.

As may be realized from FIGS. 11A and 11B. The through-via 84 may have the shape of an elongated strip in a top view of the structure. The through-via 84 may also extend crossing a single one or a plurality of multi-layer stacks 22′ in accordance with some embodiments.

It is appreciated that since dielectric liner 80′ is formed by etching dielectric region 80 (rather than through a conformal deposition process), the thickness of dielectric liner 80′ may be controlled, and the thickness of different portions of dielectric liner 80′ may be different from each other, even if they are measured at the same level. Also, the thickness of dielectric liner 80′ in one cross-section may be different from the thickness of dielectric liner 80′ in another cross-section, even if they are measured at the same level. For example, the thickness T1 in FIG. 11A may be different from, and may be smaller than, thickness T2 in FIG. 11B. This may minimize the difficulty in the gap-filling, while at the same time minimize the risk of electrical shorting and leakage.

Also since dielectric liner 80′ is formed by etching dielectric region 80 rather than through a conformal deposition process, the thicknesses of dielectric liner 80′ at different levels may also be equal to or different from each other. For example, in FIG. 11A, the top thickness T1, middle thickness T1′, and bottom thickness T1″ may be the same as each other or different from each other. In FIG. 11B, the top thickness T2, middle thickness T2′, and bottom thickness T2″ may be the same as each other or different from each other.

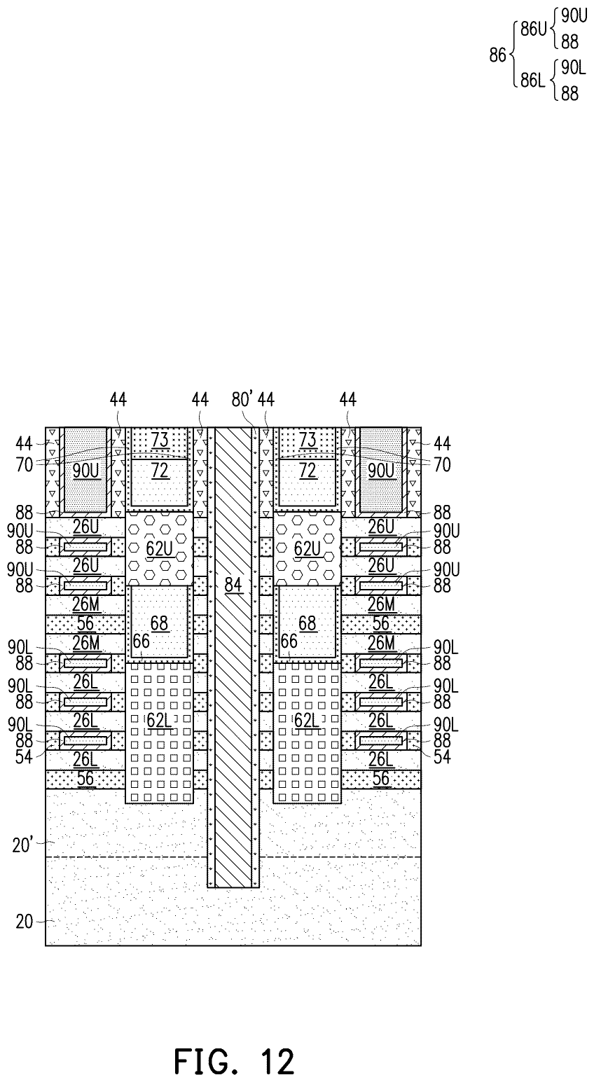

In accordance with alternative embodiments, the formation of dielectric liner 80′, instead of through forming the COPDE region and then etching the COPDE region, may be formed through a conformal deposition process to deposit the conformal dielectric liner 80′ extending into trench 76. A metallic material is then deposited to fill the remaining trench 76. A planarization process is subsequently performed to remove excess portions of the conformal dielectric liner 80′ and the metallic material higher than dummy gate stacks 42. The resulting structure is essentially the same as shown in FIG. 12, except that the conformal dielectric liner 90′ includes a portion directly underlying through-via 84.

The dummy gate stacks 42 as shown in FIGS. 11A and 11B are then removed in one or more etching steps, so that recesses are formed between the gate spacers 44, and extend to a level lower than multi-layer stacks 22′ (FIG. 11A, also refer to FIG. 2 as a reference). The sidewalls of multi-layer stacks 22′ are thus exposed, and the sidewalls of nanostructures 26U and 26L and dummy semiconductor layers 24A are exposed.

Dummy semiconductor layers 24A are then removed, so that the recesses extend laterally between semiconductor nanostructures 26U and 26L. In accordance with some embodiments, the dummy gate stacks 42 and the dummy gate dielectrics 36 are removed by isotropic etching processes. Dummy semiconductor layers 24A can be removed by any acceptable etch process that selectively etches the material of the dummy semiconductor layers 24A at a faster rate than the materials of the semiconductor nanostructures 26, the inner spacers 54, and the isolation structures 56. The etching may be isotropic.

In FIG. 12, replacement gate stacks 86 (including gate stacks 86U and 86L) are formed, which include gate dielectrics 88 and gate electrodes 90 (further including gate electrodes 90U and 90L). The respective process is illustrated as process 238 in the process flow 200 as shown in FIG. 41. Gate dielectrics 88 may be conformally formed on the channel regions of the semiconductor nanostructures 26. Each of the gate dielectrics 88 may include an interfacial layer (IL), which may be formed of or comprises an oxide such as silicon oxide or a metal oxide, a silicate such as a metal silicate, combinations thereof, multi-layers thereof, or the like. Each of the gate dielectrics 88 may also include a high dielectric constant (high-k) dielectric layer formed of a high-k dielectric material having a k-value greater than 3.9, and possibly greater than about 7.0. The high-k dielectric material may comprise a metal oxide or a metal nitride of metals such as hafnium, aluminum, zirconium, lanthanum, manganese, barium, titanium, lead. The formation methods of the gate dielectrics 88 may include molecular-beam deposition (MBD), ALD, PECVD, and the like.

Further referring to FIG. 12, lower gate electrodes 90L are formed on the gate dielectrics 88. The lower gate electrodes 90L are disposed between the lower semiconductor nanostructures 26L. Accordingly, the lower gate electrodes 90L also wrap around the lower semiconductor nanostructures 26L. Upper gate electrodes 90U are formed on the gate dielectrics 88. The upper gate electrodes 90U are disposed between the upper semiconductor nanostructures 26U. Accordingly, the upper gate electrodes 90U also wrap around the upper semiconductor nanostructures 26U.

Lower gate electrodes 90L and upper gate electrodes 90U may include adhesion layers, work-function layers, a filling metal, or the like. The materials of the work-function layers are selected based on the conductivity type of the respective FET. For example, for an n-type FET, n-type work function materials such as TiAl, TiAlN, or the like may be used to form the work-function layer. For a p-type FET, p-type work function materials such as TiN may be used to form the work-function layer. In accordance with some embodiments, the upper gate electrodes 90U may be recessed to form recesses between opposing gate spacers 44, followed by filling a dielectric material into the recesses to form gate hard masks (not shown).

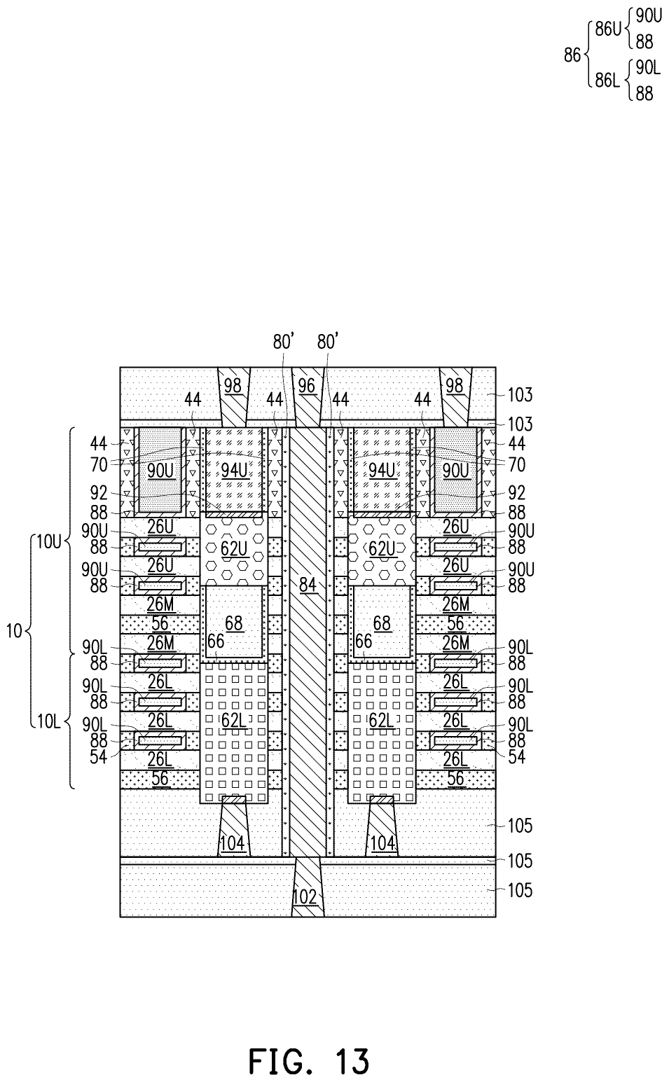

FIG. 13 illustrates the formation of source/drain silicide regions 92 and source/drain contact plugs 94U, which are formed on the upper source/drain regions 62U. Front-side dielectric layers 103 are formed, which may include an etch stop layer, an Inter-layer Dielectric (ILD), and the like. Contact pugs/vias 96 and 98 are formed in dielectric layers 103, and are electrically connected to through-via 84, source/drain contact plugs 94U, and gate electrodes 90U. The respective process is illustrated as process 240 in the process flow 200 as shown in FIG. 41.

Next, the substrate 20 (FIG. 12) is removed, for example, through etching, CMP, or the like. The bottom end of through-via 84 is exposed. In accordance with some embodiments, as shown in FIG. 13, the substrate 20 is fully removed. In accordance with alternative embodiments, substrate 20 is thinned but not fully removed. Subsequently, backside dielectric layers 105U are formed. Backside contact plug 102 is formed to penetrate through backside dielectric layers 105, and to connect to through-via 84. The respective process is illustrated as process 242 in the process flow 200 as shown in FIG. 41. The electrical connection to the lower source/drain region 62L may be made through backside contact plugs 104, which are formed in the backside dielectric layers 105 in accordance with some embodiments.

Lower nanostructure-FET 10L and upper nanostructure-FET 10U are thus formed, and collectively form CFET 10. In the illustrated example as shown in FIG. 13, two CFETs are formed on the opposing sides of through-via 84. In the respective structure, through-via 84 utilizes the space that is used by SDB region to form the through-via 84. Through-via 84 may be used for front-and-back signal routing, power supplying (VDD and/or VSS), or the like. Accordingly, the spaces that are used for electrically isolating neighboring CFETs are also used for signal and electrical interconnection. Since the interconnection is formed right next to the CFETs, the corresponding front-and-back interconnection line including the through-via 84 is short, and thus has a low resistance.

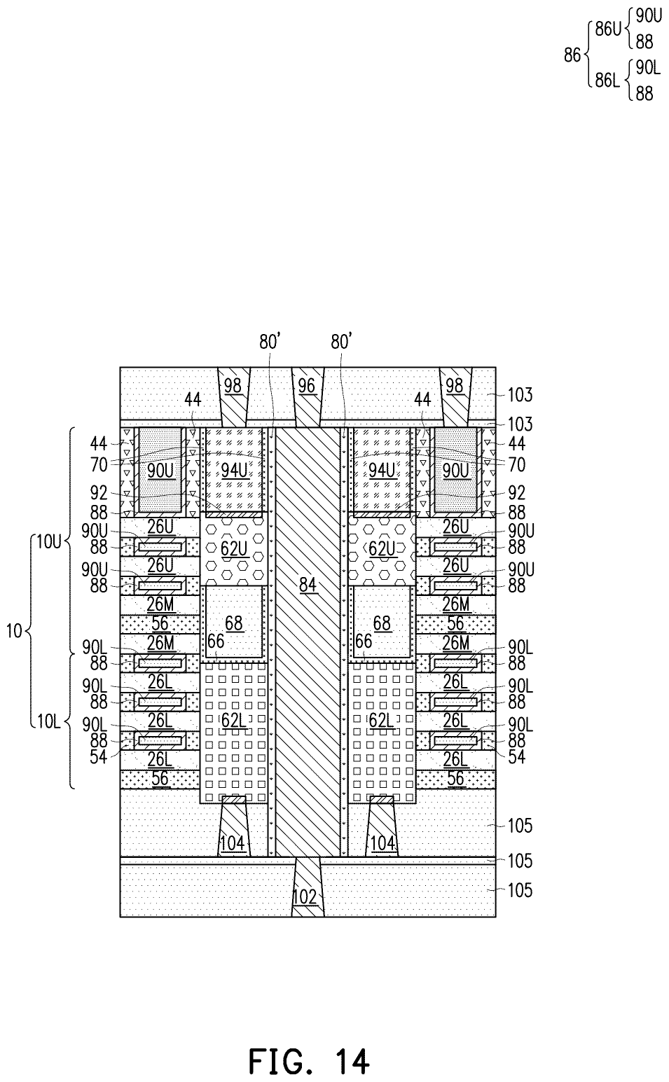

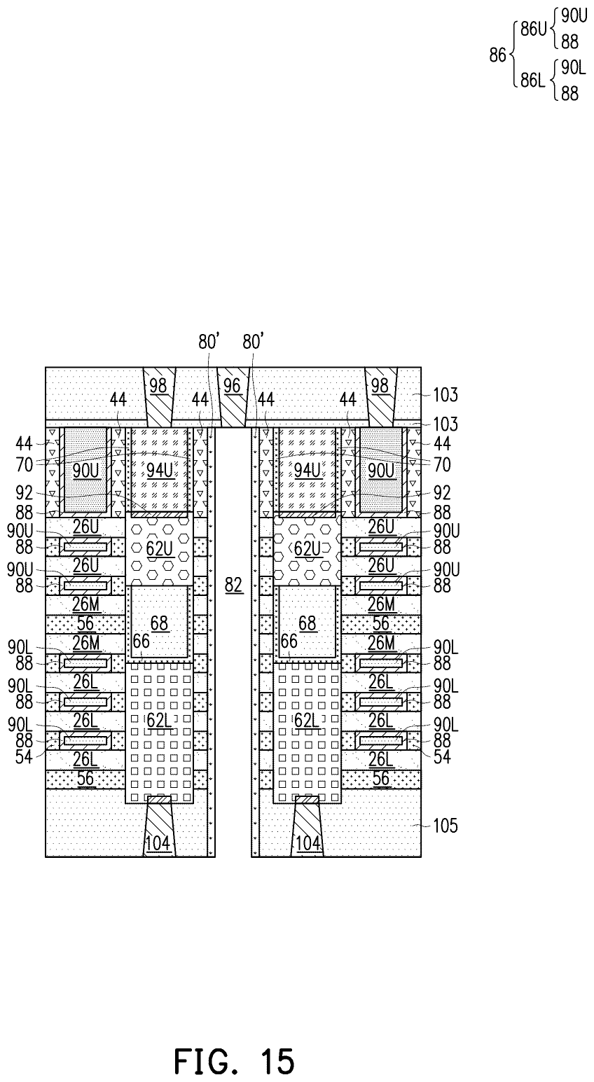

FIG. 14, FIGS. 15, 16A, and 16B, FIGS. 17-19, 20A, and 20B, FIGS. 21-31, and FIGS. 32-39 illustrate the cross-sectional views of intermediate stages in the formation of CFETs and a through-via in accordance with alternative embodiments of the present disclosure. Unless specified otherwise, the materials, the structures, and the formation processes of the components in these embodiments are essentially the same as the like components denoted by like reference numerals in the preceding embodiments. The details regarding the materials, the structures, and the formation processes provided in any of the embodiments throughout the description may be applied to any other embodiment whenever applicable.

FIG. 14 illustrates a structure in accordance with alternative embodiments. The structure shown in FIG. 14 is essentially the same as the structure shown in FIG. 13, except that dielectric liner 80′, which is formed adopting a SDB process, laterally expand to contact one or both of the source/drain regions 62U, and/or contact one or both of source/drain regions 62L and 62U. dielectric liner 80′ may also contact CESLs 70 and 66 in accordance with some embodiments.

The formation process of this structure may be essentially the same as in the preceding embodiments, except that in the process shown in FIG. 14, the corresponding etching mask for forming trench 76 has a larger opening, through which the top surfaces of some gate spacers 44 are also exposed. As a result, the corresponding trench 76 is wider, and through-via 84 may be formed wider, with a width (sidewall to sidewall) being in a range between about 15 nm and about 69 nm in accordance with some embodiments. In accordance with some embodiments as shown in FIG. 14, dielectric liner 80′ may contact the sidewalls of the vertical portions of CESL 70.

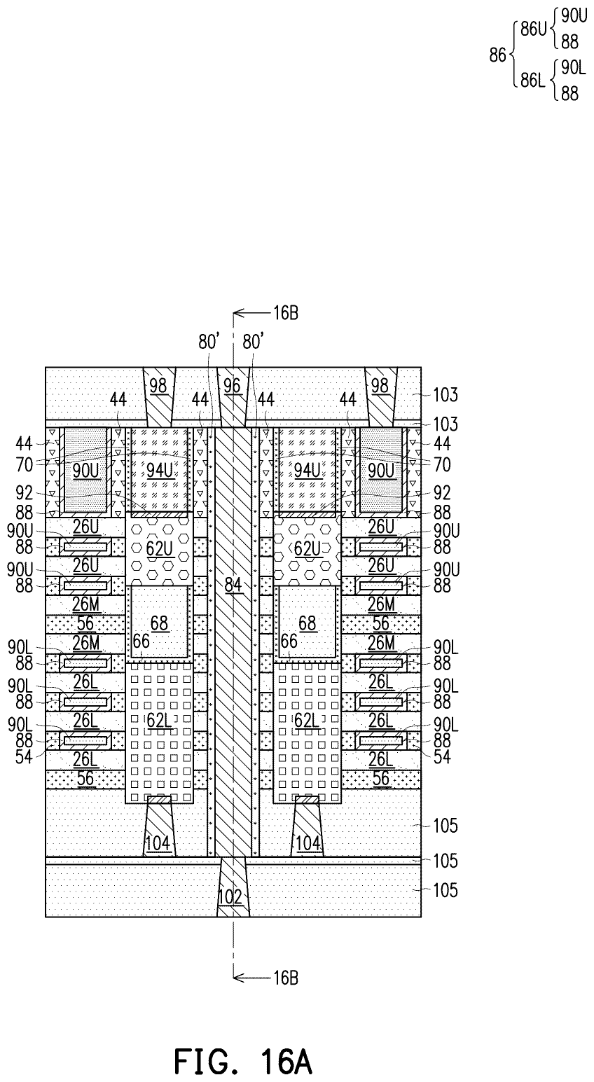

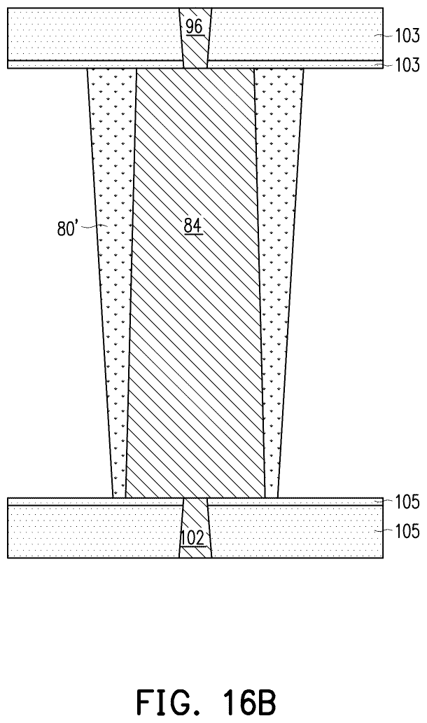

In the precedingly discussed embodiments, the through-via 84 is formed from the front side of the respective wafer. FIGS. 15, 16A, and 16B illustrate an embodiment in which the through-via 84 is formed from the backside of the respective wafer. The initial processes of these embodiments are essentially the same as illustrate in FIGS. 2 through FIGS. 9A and 9B, and dielectric region 84 has been formed from the front side of the respective wafer, as shown in FIGS. 9A and 9B. Next, the dummy gate stacks 42 and dummy semiconductor layers 24A (FIG. 9A) are removed, followed by the formation of replacement gate stacks 86. The resulting structure is shown in FIG. 15. In a subsequent process, as also shown in FIG. 15, front-side dielectric layers 103 and contact plugs 96 and 98 are formed.

Next, substrate 20 (refer to FIG. 9A) is removed, and some backside features such as dielectric layer 105 and contact plugs 104 (FIG. 15) may be formed from the backside of the respective wafer. In accordance with alternative embodiments, contact plugs 104 may not be formed. Dielectric layer 105 is planarized from the backside (the illustrated bottom side) of the wafer, until dielectric region 80, which is essentially the same as shown in FIG. 9A, is exposed from the backside of the respective wafer.

In a subsequent process, as shown in FIG. 15, the dielectric region 80 (SDB region) is etched from the backside of the respective wafer, forming trench 82. The front-side dielectric layers 103 and contact plug 96 are exposed to trench 82, and may act as the etch stop layer in accordance with some embodiments.

Referring to FIG. 16A, trench 82 is filled with a dielectric material to form through-via 84. Next, some additional dielectric layers 105 and conductive features such as conduct plug 102 may be formed on the backside of the respective wafer in accordance with some embodiments.

FIG. 16B illustrates the cross-section 16B-16B in FIG. 16A. It is appreciated that when forming trench 76 from the front side of the respective wafer, as shown in FIG. 8B, the trench 76 may be tapered, with the upper portions being increasingly wider than the respectively lower portions. The actual tapering may be less severe than as illustrated in FIG. 8B. The tapered profile of trench 76 results in the dielectric region 80 and the outer contour of dielectric liner 80′ to be tapered also, with the upper portions being increasingly wider than the respectively lower portions. The resulting profile of dielectric liner 80′ is shown in FIG. 16B.

The etching of the dielectric region 80 (FIG. 15), however, is from the backside of the respective wafer. Accordingly, the trench 82 in FIG. 15 may be tapered, with the lower portions being increasingly wider than the respective upper portions. This results in the through-via 84 to be tapered also, as shown in FIG. 16B, with the lower portions being increasingly wider than the respective upper portions. Accordingly, dielectric liner 80′ also has upper portions being increasingly thicker than the respective lower portions. In accordance with some embodiments, the inner sidewalls and the outer sidewalls of dielectric liner 80′ are straight and tilted in opposite directions.

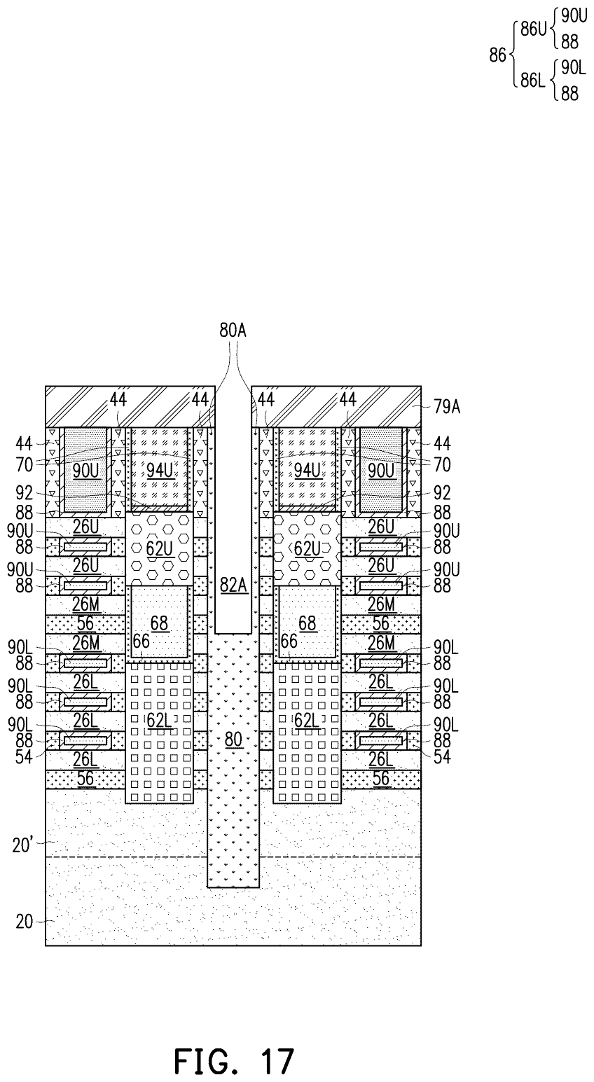

FIGS. 17-19, 20A, and 20B illustrate an embodiment in which the through-via 84 is formed from both of the front side and the backside of the respective wafer. The initial processes of these embodiments are essentially the same as illustrated in FIGS. 2 through 9A and 9B. Replacement gate stacks are then formed to replace the dummy gate stacks. The resulting structure is shown in FIG. 17. Source/drain silicide regions 92 and source/drain contact plugs 94U are also formed.

Next, further referring to FIG. 17, etching mask 79A is formed, and dielectric region 80, which is essentially the same as shown in FIG. 9A, is etched from the front side of the respective wafer, hence forming trench 82A in dielectric region 80. Etching mask 79A is then removed. Dielectric liner portion 80A, which are parts of the remaining dielectric region 80 encircling trench 82A, is thus formed.

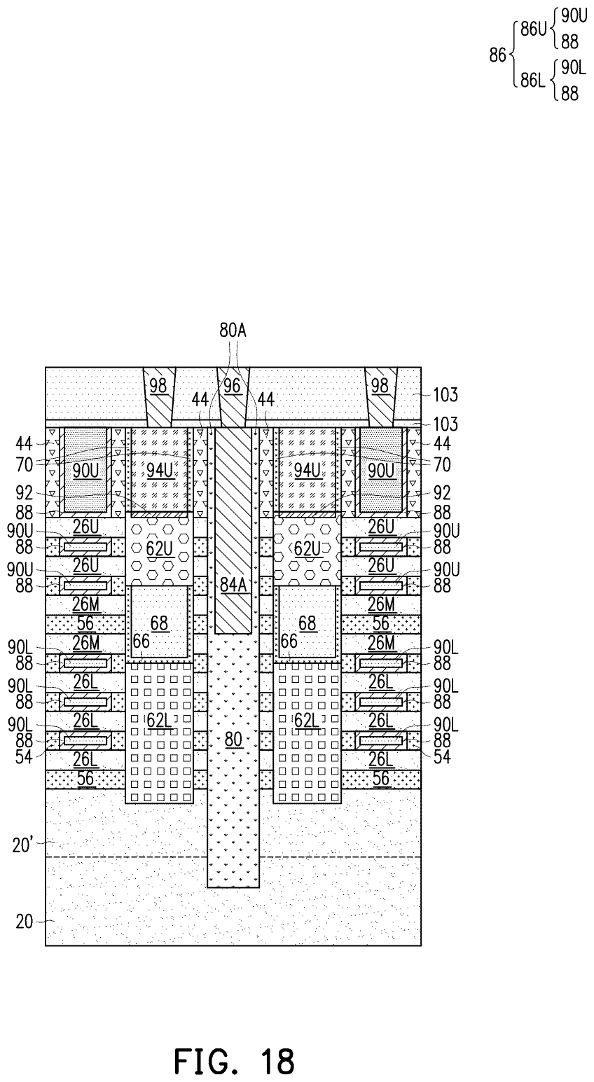

Next, referring to FIG. 18, trench 82A is filled with a conductive material to form through-via portion 84A, which is then planarized to have its top surface coplanar with the top surfaces of gate spacers 44. Dielectric layers 103 are then formed on the front side of the illustrated structure. Contact plugs 96 and 98 are also formed to connected to through-via portion 84A and source/drain contact plugs 94U, and gate electrodes 90U in accordance with some embodiments.

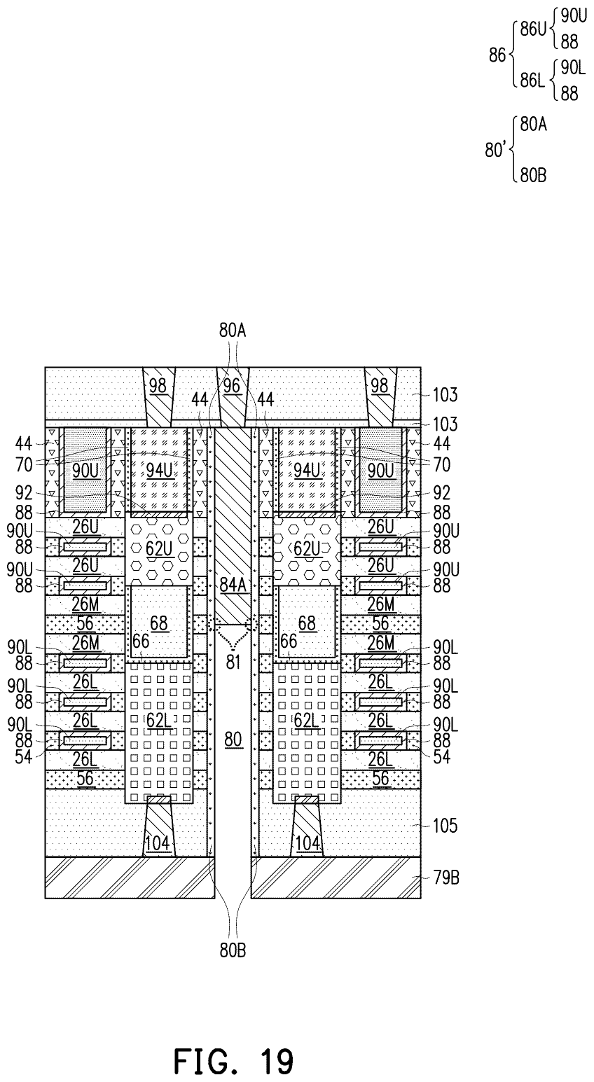

Next, substrate 20 and semiconductor strips 20′ are removed, and dielectric layer 105 is formed on the backside of the respective wafer. The resulting structure is shown in FIG. 19. In accordance with some embodiments, as shown in FIG. 19, the substrate 20 is fully removed. In accordance with alternative embodiments, substrate 20 is thinned but not fully removed. Silicide regions and backside source/drain contact plugs 104 may be formed to connect to the lower source/drain regions 62L in accordance with some embodiments.

Etching mask 79B is then formed on the backside of the respective wafer, and dielectric region 80 is etched from the back side of the respective wafer, hence forming trench 82B in dielectric region 80. Etching mask 78B is then removed. Dielectric liner portion 80B, which are parts of the dielectric region 80 encircling trench 82B, is thus formed.

Dielectric liner portions 80A and 80B collectively form dielectric liner 80′. The materials of dielectric liner portions 80A and 80B are the remaining parts of the same dielectric region 80, and hence there is no distinguishable interface separating dielectric liner portion 80A from dielectric liner portion 80B. On the other hand, since dielectric liner portions 80A and 80B are formed front the opposite sides of the respective wafer, by different etching processes, and using different etching masks, the regions 81 wherein dielectric liner portion 80A is joined to dielectric liner portion 80B may have different thicknesses. Also, in the joining regions 81, there may be abrupt thickness change. The joining regions 81 of dielectric liner portions 80A and 80B may thus be distinguishable. It is appreciated that the illustrated joining regions 81 are the portions of a ring-shaped joining region.

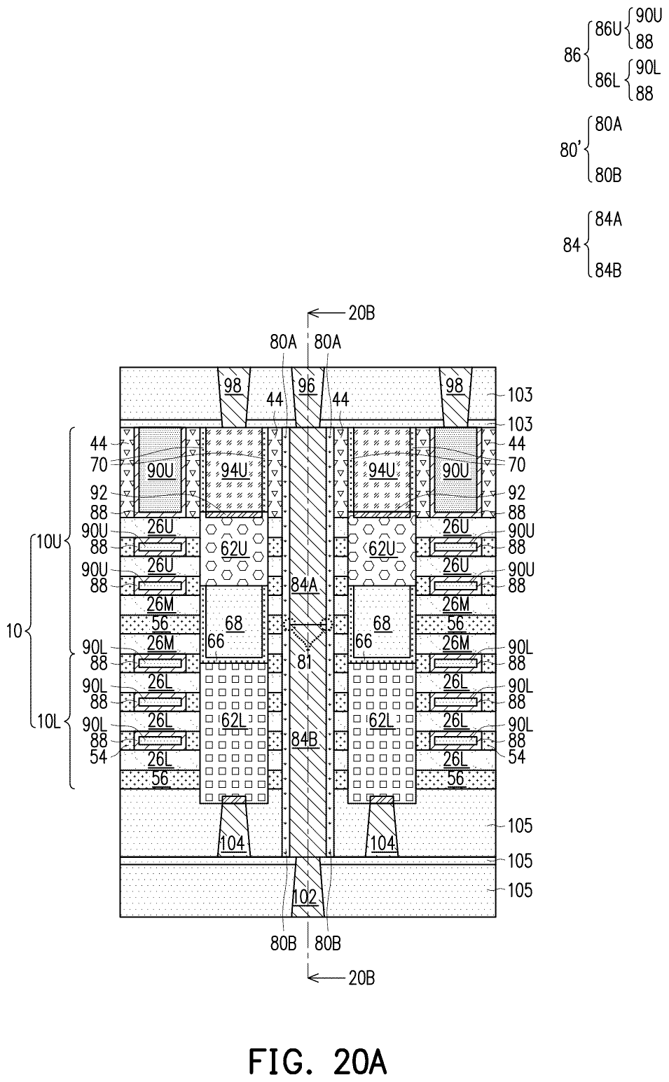

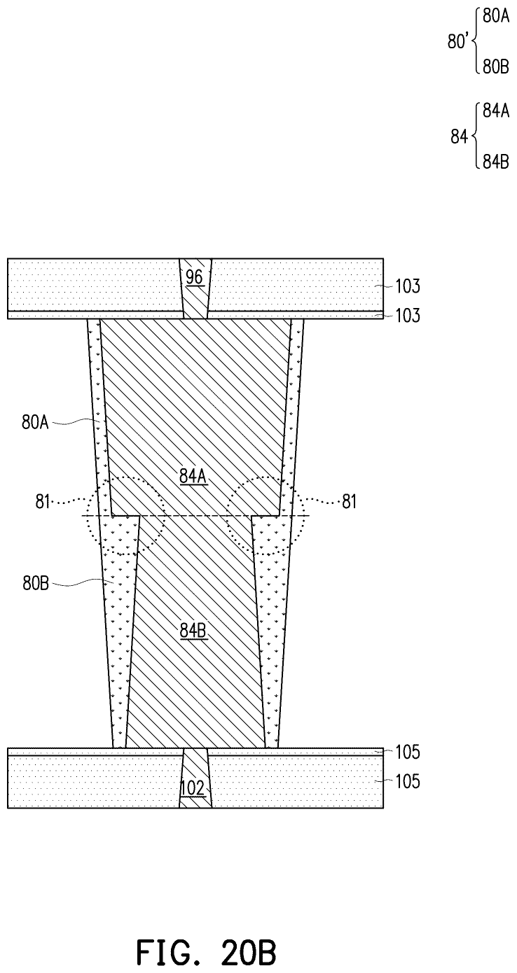

FIG. 20A illustrates the filling of trench 82B (FIG. 19) to form through-via portion 84B. Through-via portion 84B is joined to through-via portion 84B, and collectively form through-via 84. In accordance with some embodiments, through-via portions 84A and 84B may be formed of the same or different conductive (metallic) materials, which may be selected from metals such as Co, W, Ru, Cu, Mo, Ni, and alloys thereof. Through-via portions 84A and 84B thus may be, or may not be, distinguishable from each other. On the other hand, the joined region 81 of through-via portions 84A and 84B may also be found from the thickness change from dielectric liner portion 80A to dielectric liner portion 80B, so that the joining region of through-via portions 84A and 84B can be determined. In subsequent processes, contact plug 102 may be formed to connect to through-via 84 from back. Dielectric layers 105 may also be formed, with contact plug 102 being formed in dielectric layers 105.

FIG. 20B illustrates the cross-section 20B-20B in FIG. 20A in accordance with some embodiments. It is appreciated that when forming trench 76 from the front side of the respective wafer, as shown in FIG. 8B, the trench 76 may be tapered, with the upper portions being increasingly wider than the respectively lower portions. The etching the dielectric region 80 (FIG. 15), however, is from the both of the front side and the backside of the respective wafer. Accordingly, trench 82A in FIG. 17 may be tapered, with the upper portions being increasingly wider than the respective lower portions. This results in the through-via portion 84A to be tapered, as shown in FIG. 20B, with the lower portions being increasingly narrower than the respective upper portions.

On the other hand, trench 82B in FIG. 19 is formed by etching dielectric region 80 from the backside of the respective wafer. Accordingly, trench 82B may be tapered, with the lower portions being increasingly wider than the respective upper portions. This results in the through-via portion 84B to be tapered, as shown in FIG. 20B, with the lower portions being increasingly wider than the respective upper portions. Further, dielectric liner portion 80B may also have upper portions being increasingly thicker than the respective lower portions. On the other hand, dielectric liner portion 80A may have upper portions and lower portions having smaller differences than dielectric liner portion 80B. The upper portions and lower portions of dielectric liner portion 80A may also have the same thickness (within process variation).

In accordance with some embodiments, the interface between through-via portion 84B and dielectric liner portion 80A is straight, and the interface between through-via portion 84B and dielectric liner portion 80B are straight. There is the abrupt thickness change in regions 81. Also, there may be a step formed, which includes the sidewall of dielectric liner portion 80A, the sidewall of dielectric liner portion 80B, and a top surface connecting the sidewall of dielectric liner portion 80A to the sidewall of dielectric liner portion 80B.

It is appreciated that since dielectric liner 80′ is formed by etching dielectric region 80, the thickness of dielectric liner 80′ may be controlled, and the thickness of different portions of may be different from each other, even if they are measured at the same level. Also, the thickness of dielectric liner 80′ in one cross-section may be different from the thickness of dielectric liner 80′ in another cross-section, even if they are measured at the same level. The thickness differences may be essentially the same as, and may be realized from the discussion of, the thicknesses T1, T1′, and T1″ in FIG. 11A and the thicknesses T2, T2′, and T2″ in FIG. 11B.

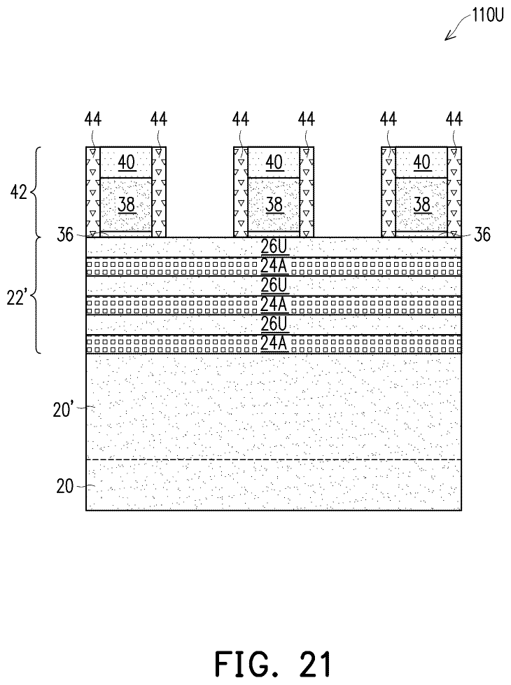

FIGS. 21 through 31 illustrate the cross-sectional views in the formation of CFETs and through-vias in accordance with alternative embodiments. The corresponding formation process of the CFETs is also referred to as a parallel formation process. FIGS. 21-25 illustrate the formation of an upper wafer 110 and upper FETs 10U in the upper wafer 110 in accordance with some embodiments. A brief formation process is discussed below. It is appreciated that some details of a plurality of processes may be the same as or may be realized from the discussion of the embodiments as shown in FIGS. 1 through 13, and hence these details may not be discussed herein.

Referring to FIG. 21, upper wafer 110U is formed. Multi-layer stack 22′ is formed. The multi-layer stack 22′ as shown in FIG. 21 may be essentially the same as the upper portion of the multi-layer stack 22′ as shown in FIG. 3, which upper portion is higher than the upper one of the dummy semiconductor layers 24B in FIG. 3. The formation process of the structure as shown in FIG. 21 may thus be essentially the same as discussed referring to FIGS. 2 and 3, except the lower portion of the multi-layer stack 22′ in FIG. 3 is not formed in the structure as shown in FIG. 21. Also, there may be a plurality of strips of multi-layer stack 22′ (similar to what is illustrated in FIG. 2) parallel to, and close to, each other.

Further referring to FIG. 21, a plurality of dummy gate stacks 42 are formed, each comprising a dummy gate dielectric 36, a dummy gate electrode 38, and possibly one or more mask layer 40. The plurality of dummy gate stacks 42 are also formed as a plurality of strips having lengthwise directions perpendicular to the lengthwise directions of multi-layer stack 22′. Also, the plurality of dummy gate stacks 42 are formed on the top surfaces (as shown in FIG. 21) and on the sidewalls (as can be realized from FIG. 2) of the multi-layer stack 22′. Gate spacers 44 are then formed on the sidewalls of dummy gate stacks 42. The dummy semiconductor layers 24A and semiconductor nanostructures 26U as shown in FIG. 21 are essentially the same as the dummy semiconductor layers 24A and semiconductor nanostructures 26U, respective, as discussed referring to FIGS. 2 and 3, and the details are not repeated herein.

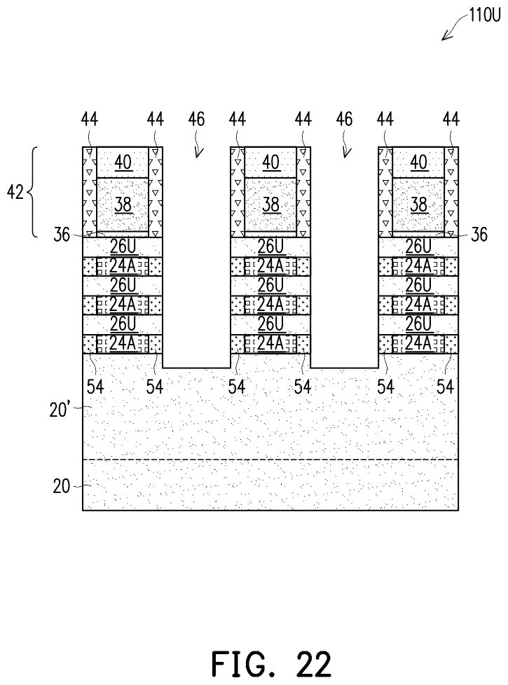

Next, as shown in FIG. 22, the multi-layer stack 22′ are etched using dummy gate stacks 42 and gate spacers 44 an as etching mask, so that recesses 46 are formed. Recesses 46 may extend to a level lower than the bottom of multi-layer stack 22′. Through recesses 46, inner spacers 54 are formed. The formation of inner spacers 54 may include an etching process that laterally etches the dummy semiconductor layers 24A (FIG. 6) to form lateral recesses, depositing a dielectric layer to fill the recesses, and etching the dielectric layer to remove the portions of the dielectric layer outside of the lateral recesses. The portions of the dielectric layer left in the lateral recesses form inner spacers 54.

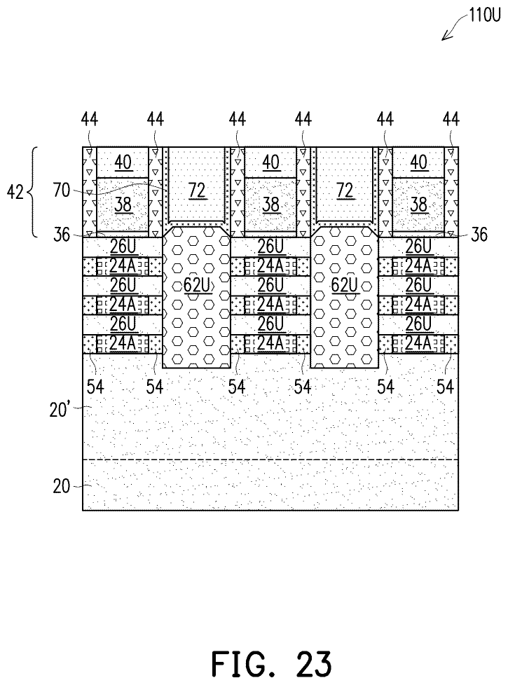

Referring to FIG. 23, upper source/drain regions 62U are formed. The formation processes are essentially the same as discussed in preceding embodiments, and are not repeated herein. Next, CESL 70 and ILD 72 are formed to fill the remaining portions of recesses 46 (FIG. 22).

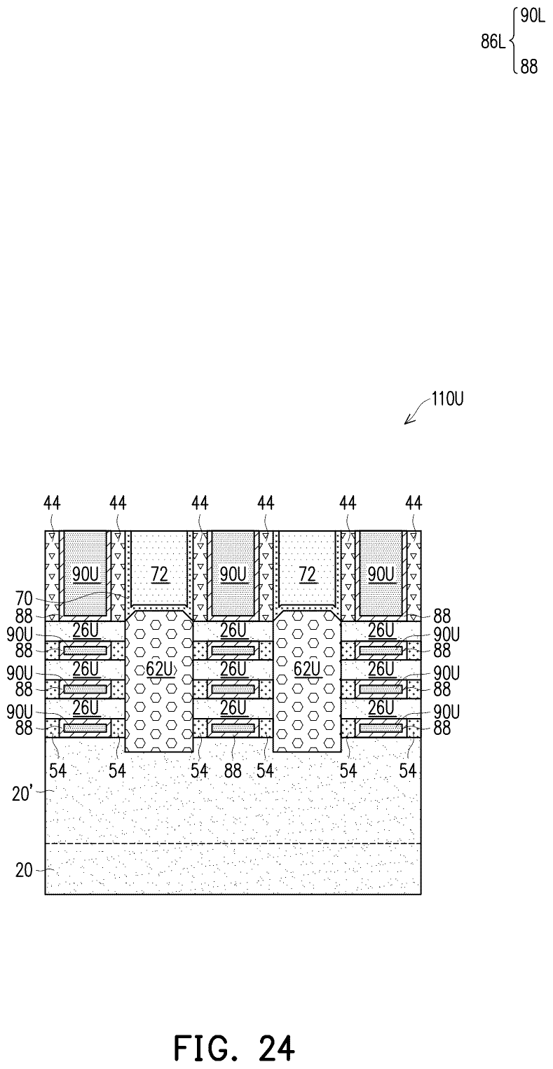

FIG. 24 illustrate the formation of replacement gate stacks 86U, which includes gate dielectrics 88 and gate electrodes 90U. The formation process may include removing dummy gate stacks 42, removing dummy semiconductor layers 24A, and forming the gate dielectrics 88 and gate electrodes 90U filling the corresponding recesses. The details of the formation processes are not repeated herein, and may be realized from the discussion of the preceding embodiments. upper nanostructure-FETs 10U are thus formed.

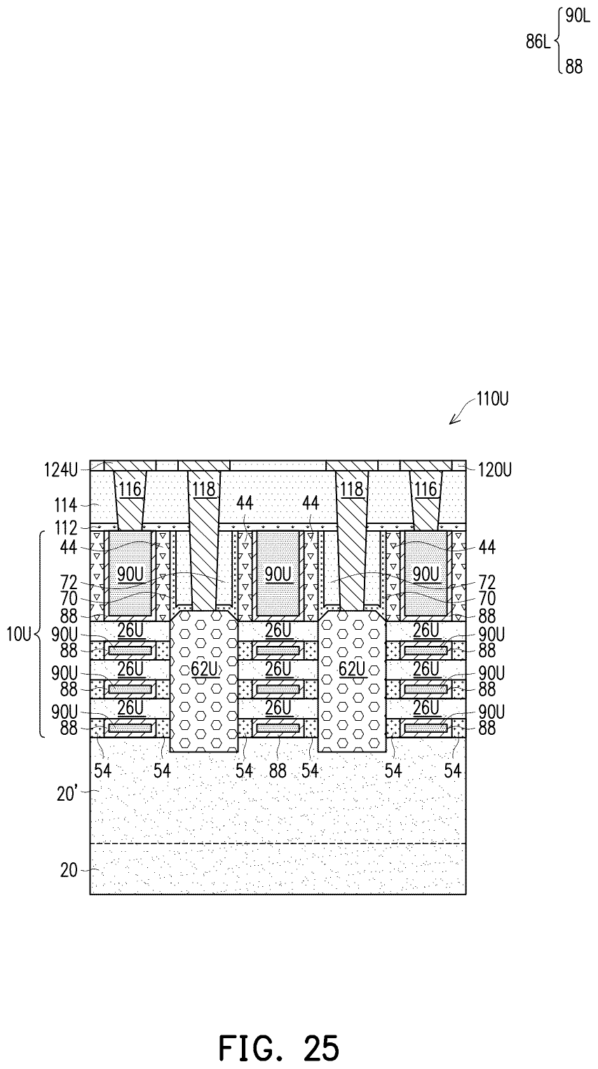

Referring to FIG. 25, gate contact plugs 116 and source/drain contact plugs 118 are formed to electrically coupling to gate electrodes 90U and upper source/drain regions 62U, respectively. Silicide regions (not shown) may also be formed on the top surfaces of the upper source/drain regions 62U. Etch stop layer 112, ILD 114, and bond layer 120U are also formed. Bond layer 120U may be formed of or comprise a silicon-containing dielectric material such as silicon oxide, silicon nitride, silicon oxynitride, silicon oxycarbide, silicon oxy carbonitride, or the like. Bond pads 124U are also formed to electrically couple to contact plugs 116 and 118. The top surfaces of bond pads 124U and bond layer 120U may be made coplanar through a planarization process such as a CMP process or a mechanical grinding process in accordance with some embodiments.

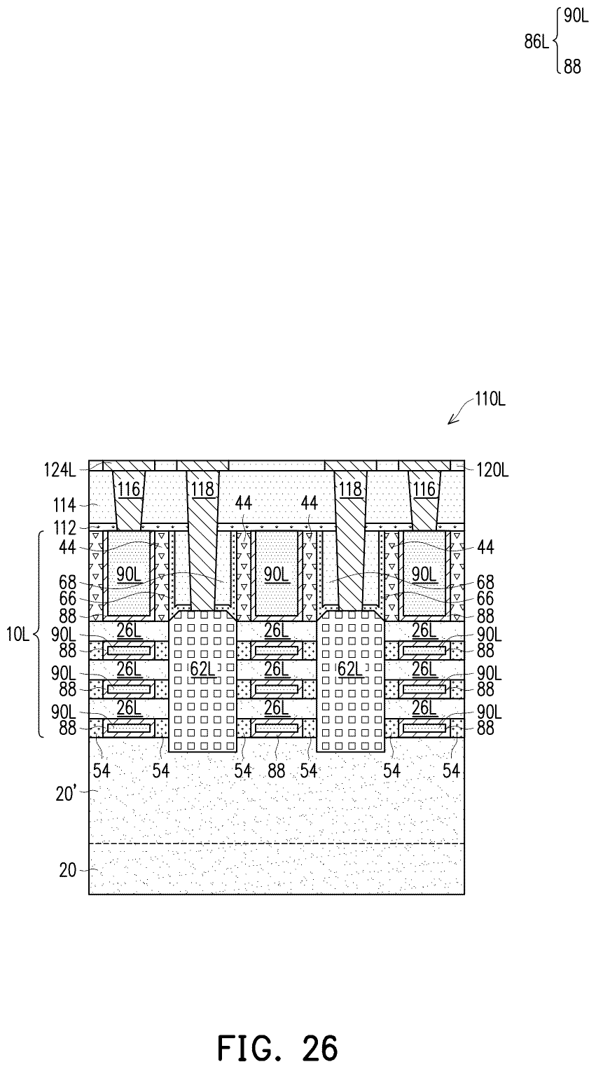

FIG. 26 illustrates the formation of lower wafer 110L and the lower nanostructure-FET 10L in the lower wafer 110L in accordance with some embodiments. The upper nanostructure-FET 10U and the lower nanostructure-FET 10L have opposite conductive types, with one being an n-type FET and the other being a p-type FET. The formation process of the lower nanostructure-FET 10L may be essentially the same as that of upper nanostructure-FET 10U, with the materials (such as source/drain regions and work function layers) being selected to suit to the conductivity type of lower nanostructure-FET 10L. The features in lower wafer 110L are denoted using same reference numerals as the corresponding features in the upper wafer 110U, except that some features may be followed by letter “L” (rather than the letter “U”) to indicate that they are the features in the lower wafer 110L.

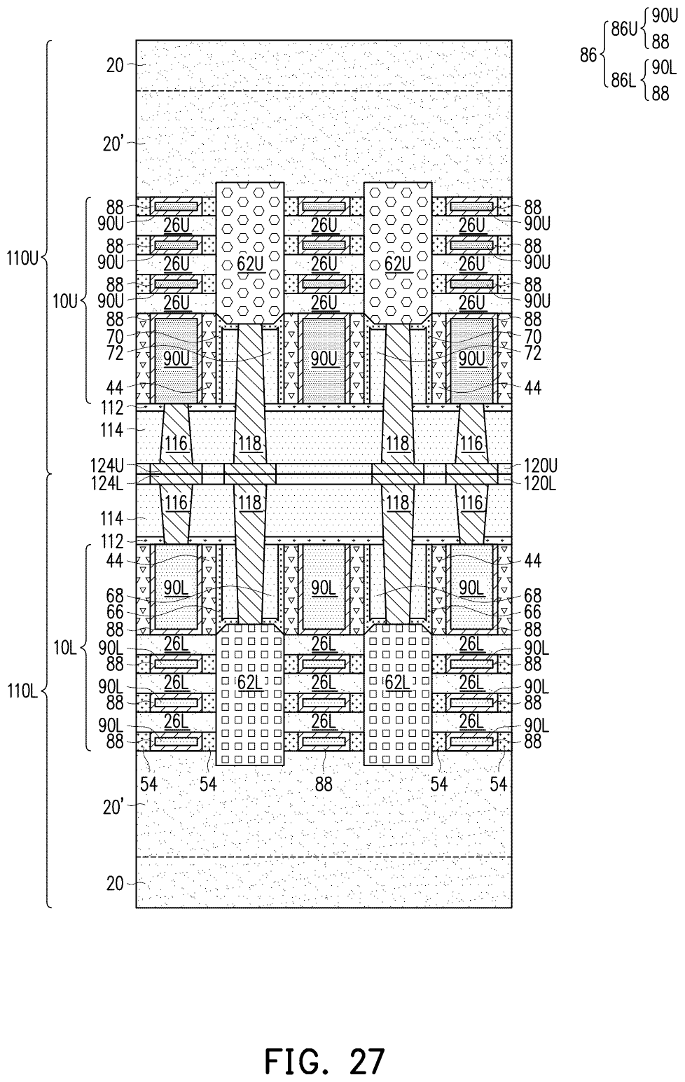

FIG. 27 illustrates the bonding of upper wafer 110U to lower wafer 110L. The bonding may be performed through hybrid bonding, with bond pads 124U in the upper wafer 110U being bonded to the bond pads 124L in the lower wafer 110L, and dielectric layer 120U in the upper wafer 110U being bonded to the dielectric layer 120L in the lower wafer 110L. Upper nanostructure-FETs 10U are thus electrically connected to lower nanostructure-FET 10L.

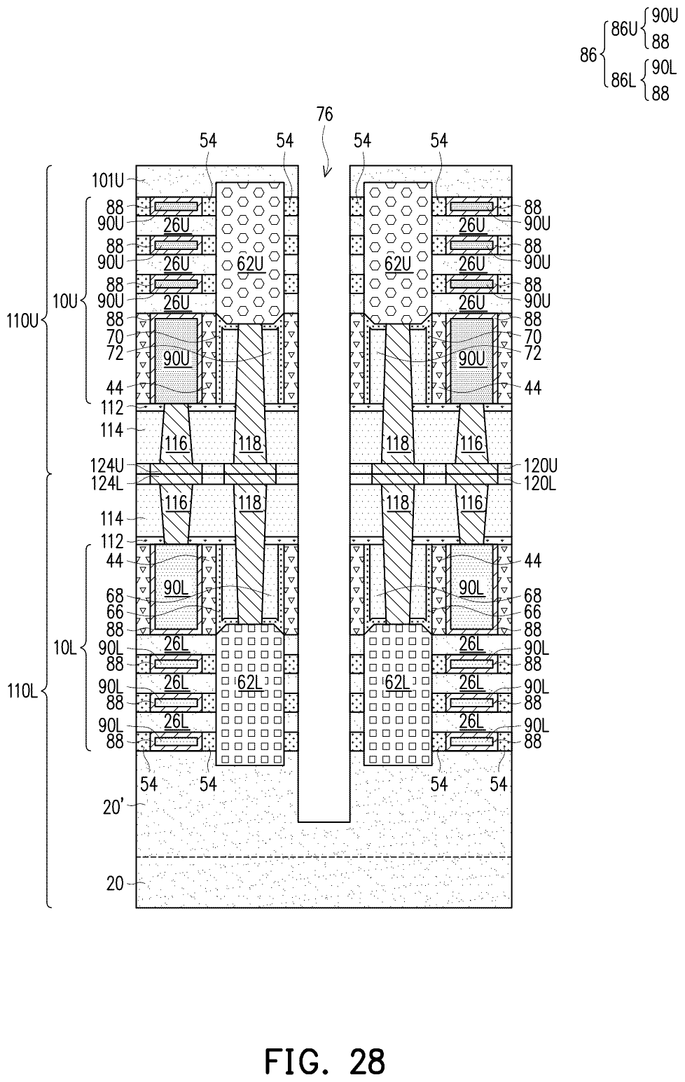

Next, the substrate 20 in the upper wafer 110U is removed, for example, through etching. Dielectric layer 101U is then formed and is planarized to form a planar top surface. The resulting structure is shown in FIG. 28. In accordance with alternative embodiments, the substrate 20 in the upper wafer 110U is thinned (but not fully removed), for example, through a CMP process or a mechanical grinding process.

The gate stack 86U between two neighboring source/drain regions 62U, the gate stack 86L between two neighboring source/drain regions 62L, the nanostructures 26U and 26L, and some dielectric layers are then etched to form trench 76, which extends from dielectric layer 101U all the way to the semiconductor strip 20′ in the lower wafer 110L. The etching includes a plurality of anisotropic etching processes to etch different materials.

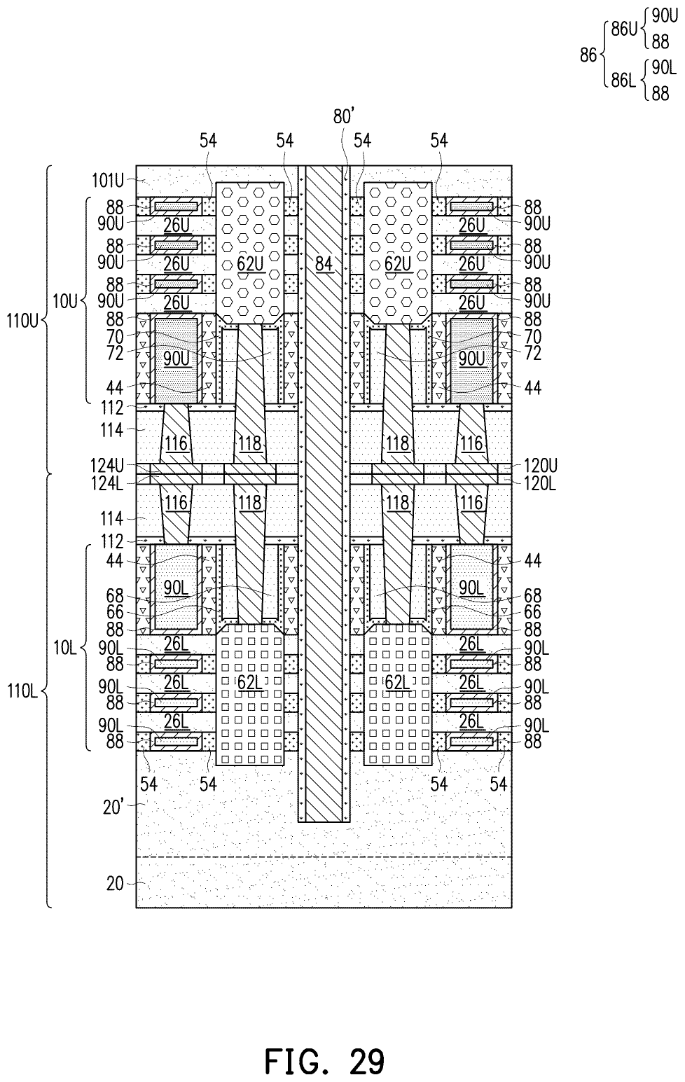

Referring to FIG. 29, dielectric liner 80′ and through-via 84 are formed in accordance with some embodiments. The formation process also includes filling a dielectric material into trench 76, and performing a planarization process to form a dielectric region (a SDB region). The details of the dielectric region may be found referring to preceding embodiments. The dielectric region is then etched, followed by filling a conductive material into the respective opening to form through-via 84.

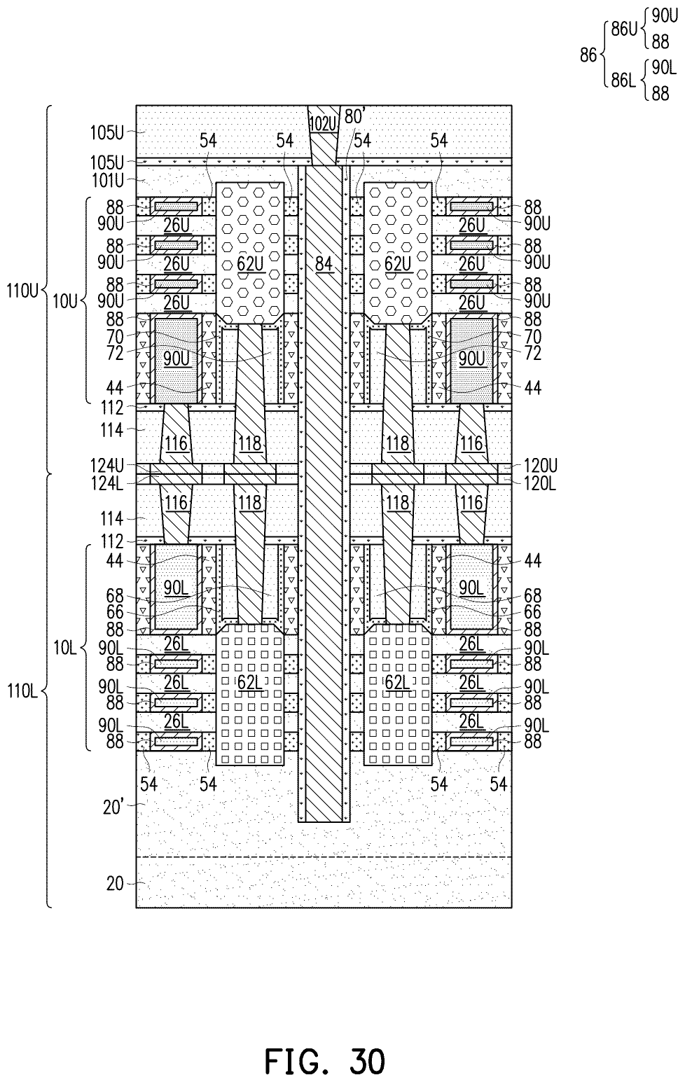

Referring to FIG. 30, backside dielectric layers 105U are formed, and may include an etch stop layer and an ILD. Backside contact plug 102U is formed to penetrate through backside dielectric layers 105U. Dielectric layers 105U and contact plug 102U are referred to as backside features since they are on the backside of the upper wafer 110U.

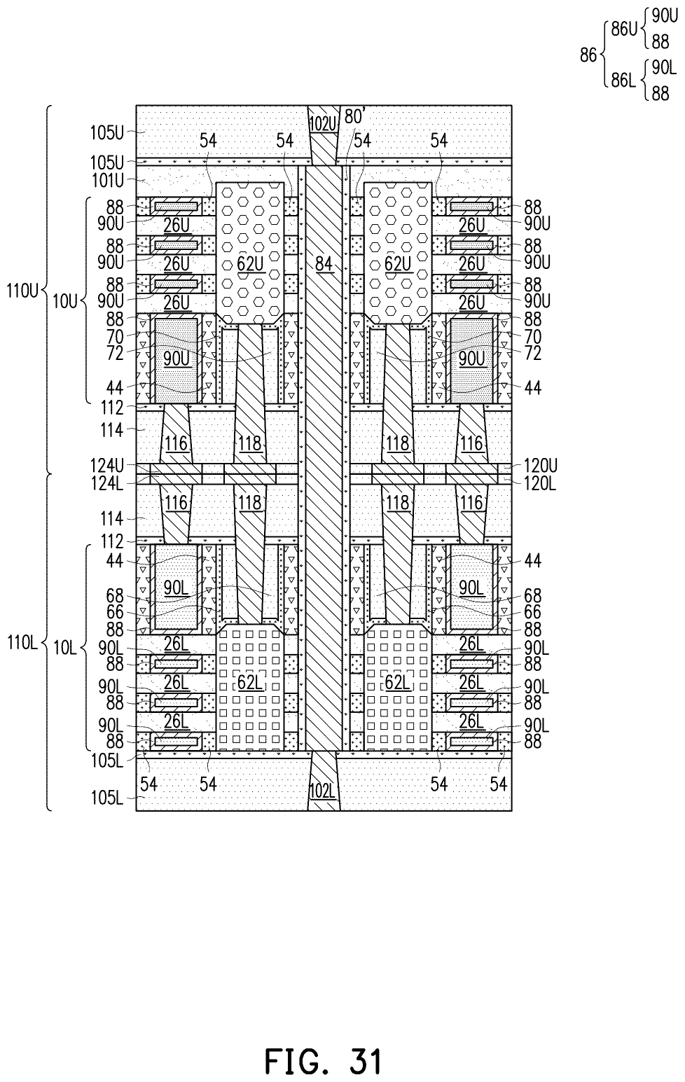

FIG. 31 illustrates the removal of substrate 20 (FIG. 30) from lower wafer 110L, and the formation of backside dielectric layer 105L and contact plug 102L, which are on the backside of the lower wafer 110L. In accordance with some embodiments, as shown in FIG. 31, the substrate 20 in the lower wafer 110L is fully removed. In accordance with alternative embodiments, the substrate 20 in the lower wafer 110L is thinned but not fully removed. Through-via 84 electrically connects contact plug 102U to back contact plug 102L. Contact plugs 102U and 102L may be further connected to a signal line, a power line, etc. for electrical and signal interconnection. In the resulting structure, lower nanostructure-FETs 10L and upper nanostructure-FETs 10U are bonded in a face-to-face pattern.

In the embodiments as shown in FIGS. 29 and 30, through-via 84 is formed from the backside of upper wafer 110U. In accordance with alternative embodiments, through-via 84 may be formed from the backside of lower wafer 110L. In accordance with yet alternative embodiments, through-via 84 may be formed from both of the backside of upper wafer 110U and the backside of lower wafer 110L. The details of the resulting dielectric liner 80′ and through-via 84 may be found in the discussion of the preceding embodiments, including the discussion of FIGS. 11A, 11B, 16B, and 20B.

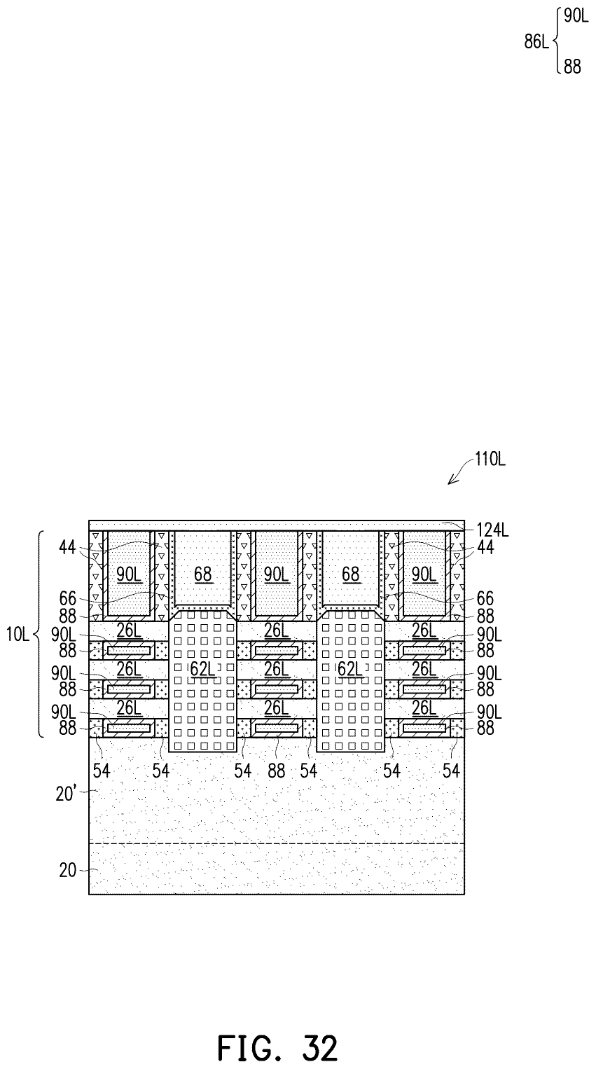

FIGS. 32 through 39 illustrate the cross-sectional views in the formation of CFETs and through-vias in accordance with alternative embodiments. The corresponding formation process of the CFETs is also referred to a sequential formation process. In these embodiments, lower nanostructure-FETs 10L are formed first, and then upper nanostructure-FETs 10U are formed over the already formed lower nanostructure-FETs 10L. A brief formation process is discussed below. It is appreciated that the details of a plurality of processes in accordance with these embodiments may be the same as or may be realized from the discussion of the proceeding embodiments, and hence these details may not be repeated herein.

Referring to FIG. 32, lower wafer 110L is formed. The formation process of the structure as shown in FIG. 32 may be essentially the same as discussed referring to the formation of the upper wafer 110U as shown in FIG. 24, which formation process is also discussed referring to FIGS. 2 and 3. Accordingly, the details of the formation processes are not repeated herein. Lower nanostructure-FET 10L is formed in lower wafer 110L, and includes gate stacks 86L, which includes replacement gate dielectrics 88 and replacement gate electrodes 90L therein. Gate stacks 86L extend to the spaces between neighboring semiconductor nanostructures 26U.

As also shown in FIG. 32, bond layer 124L is formed. In accordance with some embodiments, bond layer 124L is formed through a deposition process such as CVD, ALD, PECVD, or the like. A planarization process may be performed to level the top surface of bond layer 124L. Bond layer 124L may be formed of or comprise a silicon-containing dielectric material such as silicon oxide, silicon nitride, silicon oxynitride, silicon oxycarbide, silicon oxy carbonitride, or the like.

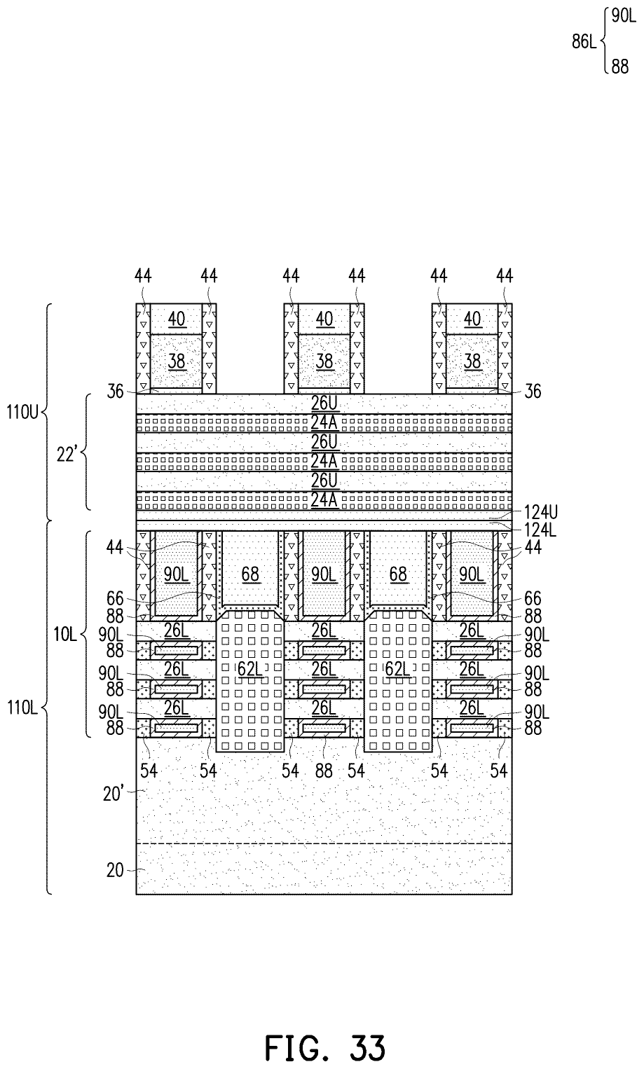

Next, as shown in FIG. 33, multi-layer stack 22′ are formed, and are bonded to the underlying lower wafer 110L through bond layer 124U. Bond layer 124U may also be formed of or comprise a silicon-containing dielectric material such as silicon oxide, silicon nitride, silicon oxynitride, silicon oxycarbide, silicon oxy carbonitride, or the like. The multi-layer stack 22′ may the essentially the same as the upper portion of the multi-layer stack as shown in FIG. 21, which upper portion is higher than the dummy semiconductor layer 24B in FIG. 3. The top layer in multi-layer stack 22′ may be a semiconductor nanostructures 26U, which may be formed of silicon. The bottom layer in multi-layer stack 22′ may be a dummy semiconductor layers 24A, which may be formed of silicon germanium.

In accordance with some embodiments, the formation and the bonding of bond layer 124U and the multi-layer stack 22′ may include forming alternating layers of semiconductor nanostructures 26U and dummy semiconductor layers 24A on a semiconductor substrate, and depositing a bond layer 124U on the multi-layer stack 22′. The alternating layers of semiconductor nanostructures 26U and dummy semiconductor layers 24A are epitaxially grown in a plurality of epitaxy processes, each forming one of semiconductor nanostructures 26U and dummy semiconductor layers 24A. The resulting structure is thus referred to as upper wafer 110U. The upper wafer 110U is then bonded to lower wafer 110L through the bonding of bond layer 124U to bond layer 124L.

In accordance with alternative embodiments, instead of pre-forming upper wafer 110U and bonding upper wafer 110U to lower wafer 110L, the bond layer 124U is first formed on a semiconductor layer (not shown), which may be a silicon germanium layer. The bond layer 124U is then bonded to bond layer 124L in the lower wafer 110L along with the overlying semiconductor layer. The semiconductor layer is then thinned to a desirable thickness to form the bottom dummy semiconductor layer 24A. Alternating layers of semiconductor nanostructures 26U and dummy semiconductor layers 24A are then epitaxially grown on the bottom dummy semiconductor layer 24A.

Further referring to FIG. 33, a plurality of dummy gate stacks 42 are formed, each comprising a dummy gate dielectric 36, a dummy gate electrode 38, and possibly one or more mask layer 40. The plurality of dummy gate stacks 42 are also formed as a plurality of strips having lengthwise directions perpendicular to the lengthwise directions of multi-layer stack 22′. Also, the plurality of dummy gate stacks 42 extend on the top surfaces (as shown in FIG. 33) and on the sidewalls (as can be realized from FIG. 2) of multi-layer stack 22′. Gate spacers 44 are then formed on the sidewalls of dummy gate stacks 42.

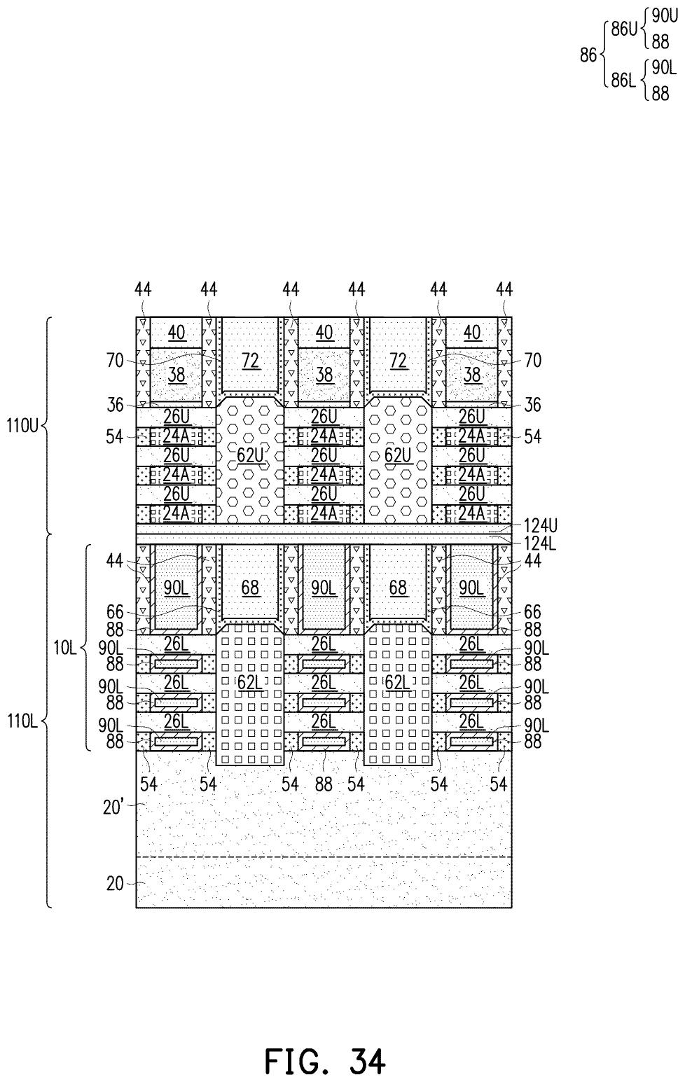

Next, as shown in FIG. 34, inner spacers 54, source/drain regions 62U, CESL 70, and ILD 72 are formed. The formation process may include anisotropically etching multi-layer stack 22′ to from openings, until bond layer 124U is exposed. Inner spacers 54 are then formed by laterally recessing dummy semiconductor layers 24A to form lateral recesses, and filling a dielectric material in the lateral recesses. Source/drain regions 62U are then formed, followed by the formation of CESL 70 and ILD 72.

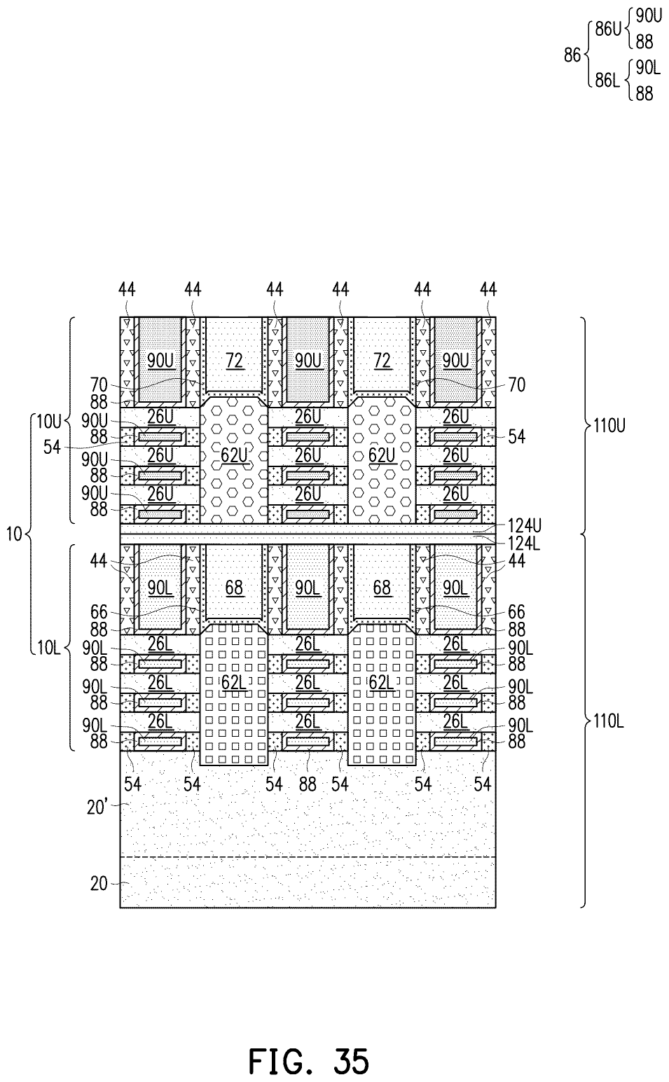

Referring to FIG. 35, the dummy gate stacks 42 as shown in FIG. 34 are removed, and replacement gate stacks 86U are formed, and extend to the spaces between neighboring semiconductor nanostructures 26U. The formation of gate stacks 86U are not discussed in detail herein, and may be found from the discussions of the preceding embodiments. Upper transistor 10U is thus formed. The lower nano-structure FETs 10L and upper nano-structure FETs 10U collectively form CFET 10. Throughout the description, the features higher than bond layer 124L are collectively referred to as upper wafer 110U.

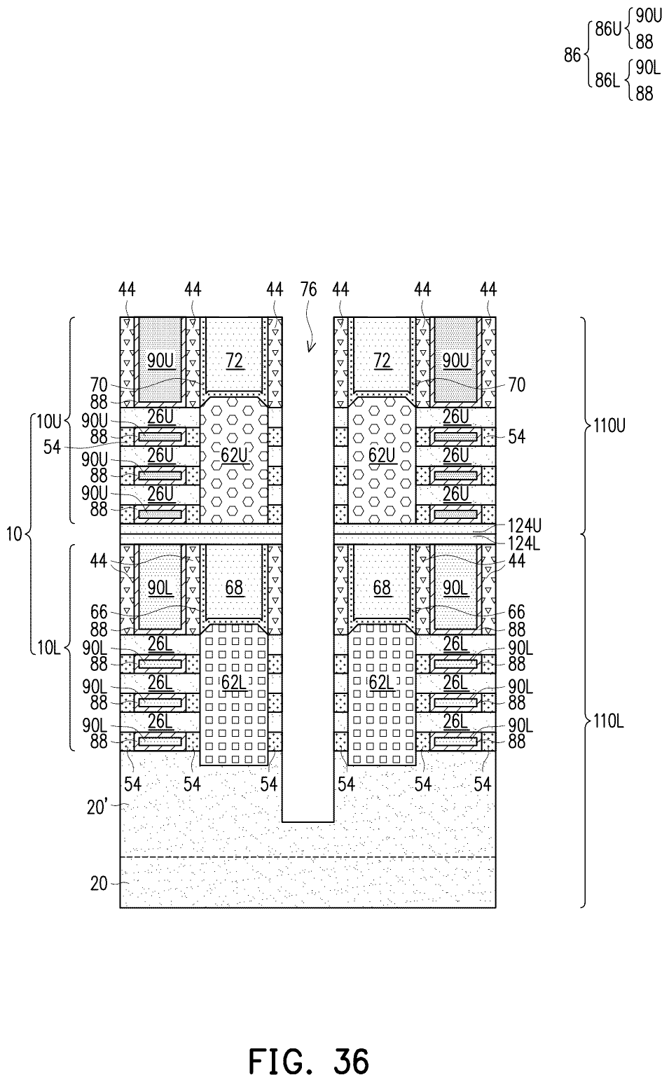

Referring to FIG. 36, the gate stack 86U (including gate electrodes 90U) between two neighboring source/drain regions 62U, the two neighboring gate stack 86L (including gate electrodes 90L) between two neighboring source/drain regions 62L, and the overlying and underlying structures of gate stacks 86U and 86L are etched to form a trench 76. Trench 76 extends from the top surface of ILD 72 into the semiconductor strip 20′ in the lower wafer 110L. The etching includes a plurality of anisotropic etching processes, with the sidewalls of upper wafer 110U and lower wafer 110L facing trench 76 being straight (within process variations).

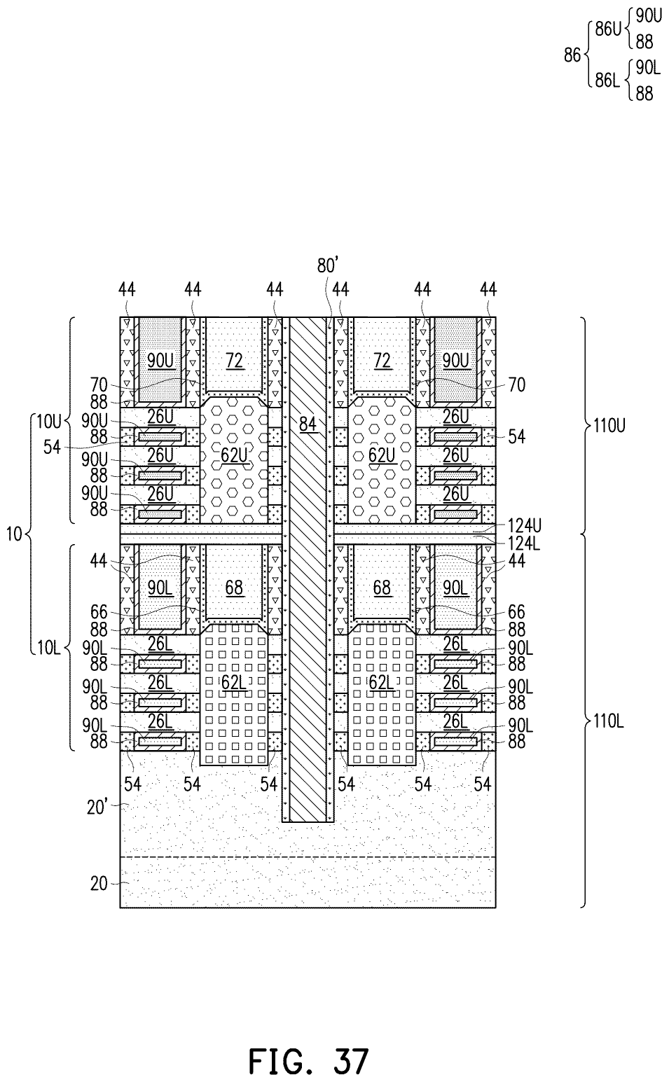

Next, as shown in FIG. 37, dielectric liner 80′ and through-via 84 are formed in the trench 76. The formation process also includes filling a dielectric material into the opening, and performing a planarization process to form a dielectric region (a SDB region). The dielectric region is then etched, followed by filling a conductive material into the respective opening to form through-via 84.

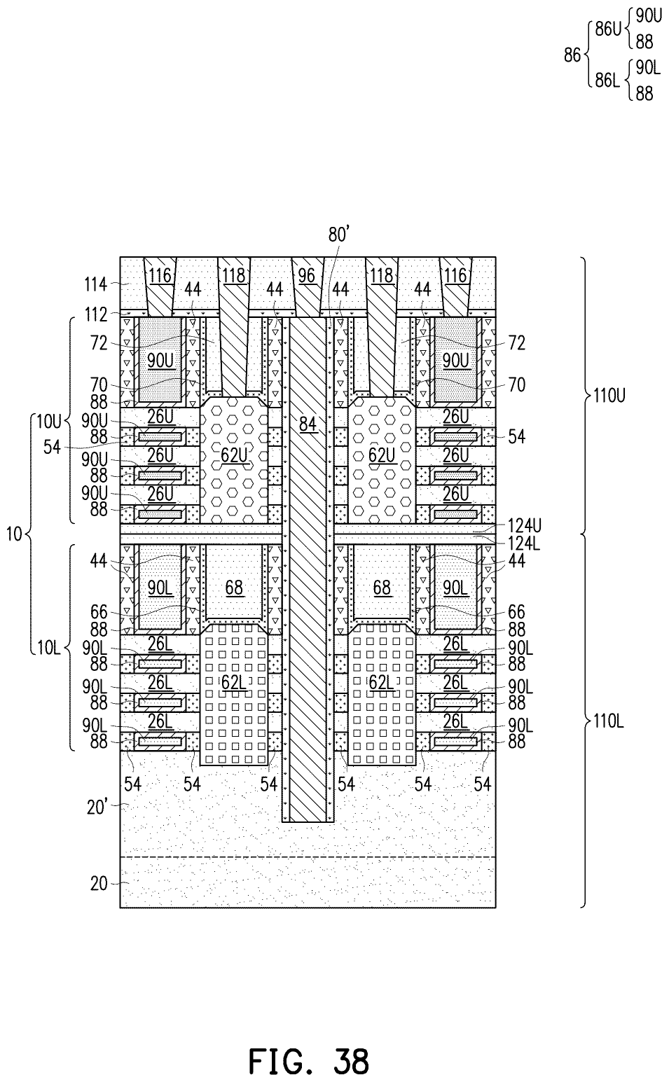

FIG. 38 illustrates the formation of etch stop layer 112, ILD 114, and front-side contact plugs 96, 116, and 118. Front-side contact plugs 96, 116, and 118 extend into etch stop layer 112 and ILD 114. Contact plugs 96, 116, and 118 are connected to the through-via 84, gate electrodes 90U, and source/drain regions 62U, respectively. Source/drain silicide layers (not shown) may be formed on source/drain regions.

It is appreciated that since dielectric liner 80′ is formed by etching dielectric region 80, the thickness of dielectric liner 80′ may be controlled, and the thickness of different portions of may be different from each other, even if they are measured at the same level. Also, the thicknesses of dielectric liner 80′ measured at different levels may be different from each, even if they are in a same cross-section.

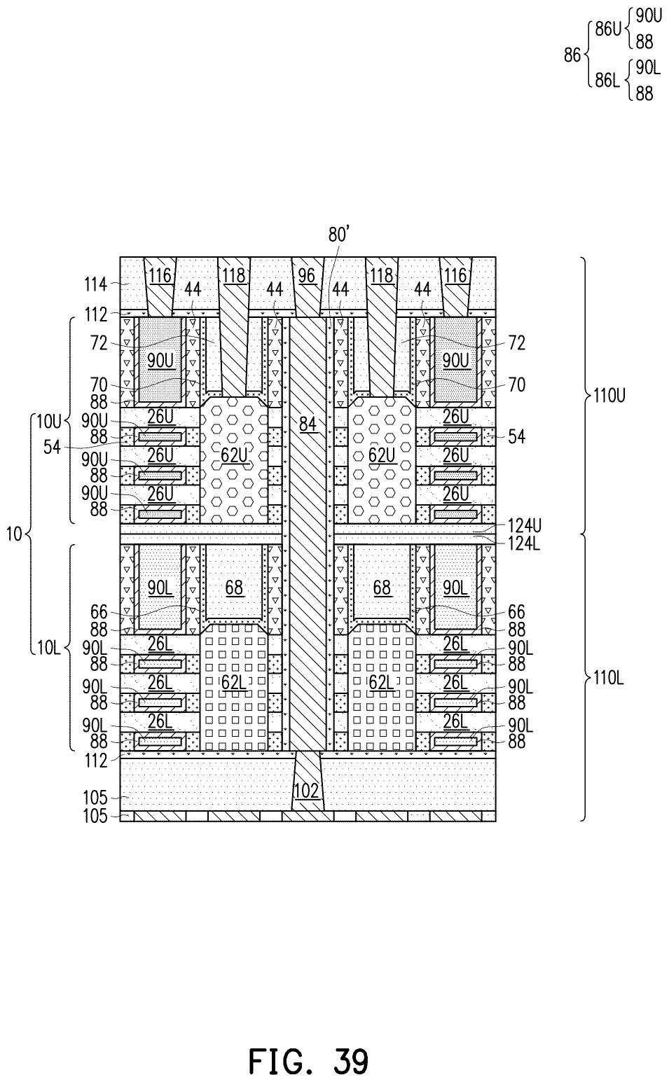

Next, the substrate 20 in the lower wafer 110L is removed in accordance with some embodiments, for example, through etching, CMP, and/or the like. The resulting structure is shown in FIG. 39. The bottom end of through-via 84 may be exposed. In accordance with some embodiments, as shown in FIG. 39, the substrate 20 in the lower wafer 110L is fully removed. In accordance with alternative embodiments, substrate 20 is thinned but not fully removed.

Subsequently, backside etch stop layer 112 and dielectric layers 105 are formed, as shown in FIG. 39. Backside contact plug 102 may penetrate through etch stop layer 112 and backside dielectric layers 105, and to connect to through-via 84.

In the embodiments as shown in FIGS. 36 and 37, through-via 84 is formed from the front side of upper wafer 110U. In accordance with alternative embodiments, through-via 84 may be formed from the backside of lower wafer 110L. In accordance with yet alternative embodiments, through-via 84 may be formed from the both of the front side of upper wafer 110U and the backside of lower wafer 110L. The details of the resulting dielectric liner 80′ and through-via 84 may be found in the discussion of the preceding embodiments, including the discussion of FIGS. 11A, 11B, 16B, and 20B.

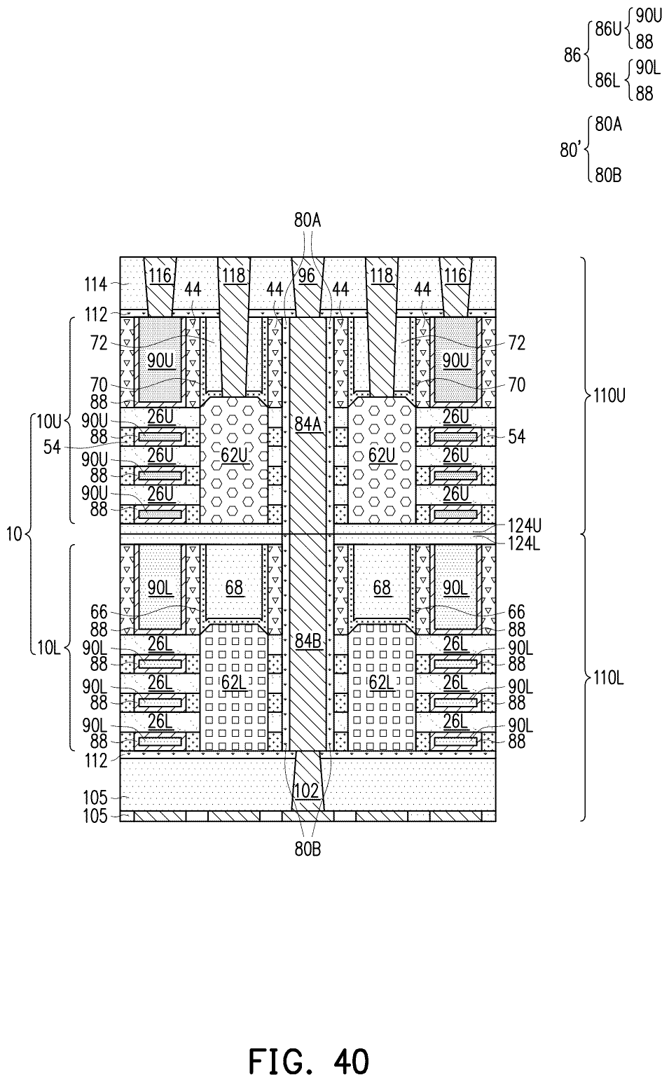

FIG. 40 illustrates an alternative embodiment in which the through-via 84 is formed from both of the front side and the backside of the respective composite wafer that includes upper wafer 110U and lower wafer 110L. Accordingly, the dielectric liner 80′ includes the portion 80A formed from the front side of upper wafer 110U, and portion 80B formed from the backside of lower wafer 110L. Also, the through-via 84 includes the portion 84A formed from the front side, and portion 84B formed from the backside. A cross-sectional view of the details of dielectric liner 80′ and through-via 84 may be found referring to FIG. 20B and the corresponding discussion.

The embodiments of the present disclosure have some advantageous features. SDB regions may be formed to isolation active regions such as the semiconductor fins or the semiconductor nanostructures of neighboring FETs. In accordance with some embodiments, through-vias are formed inside SDB regions using etching to remove the middle portions of the SDB regions, and filling the resulting trenches with a metallic material. The remaining portions of the SDB regions encircle the through-vias, and are used as isolate the through-vias from the CFETs. Accordingly, the chip area occupied by the SDB regions is well used.

In accordance with some embodiments of the present disclosure, a method comprises forming a first CFET comprising a first lower transistor; and a first upper transistor overlapping the first lower transistor; forming a second CFET comprising a second lower transistor; and a second upper transistor overlapping the second lower transistor; performing a first etching process to form a first opening, wherein the first etching process comprises etching a gate stack between the first CFET and the second CFET; and etching a plurality of alternating structures vertically aligned to the gate stack; filling the first opening with a dielectric material to form a dielectric region; performing a second etching process to etch a middle portion of the dielectric region and to form a second opening; and filling the second opening with a conductive material to form a through-via.

In an embodiment, the method further comprises forming a first contact plug overlying the through-via; and forming a second contact plug underlying the through-via, wherein the first contact plug is electrically connected to the second contact plug through the through-via. In an embodiment, at a time after the second etching process, a remaining portion of the dielectric region encircles the second opening. In an embodiment, the first etching process is performed from a front side of a respective wafer comprising the first CFET and the second CFET. In an embodiment, the first etching process is performed from a backside of a respective wafer comprising the first CFET and the second CFET. In an embodiment, the first etching process comprises a third etching process performed from a front side of a respective wafer comprising the first CFET and the second CFET; and a fourth etching process performed from a backside of the respective wafer.

In an embodiment, the method further comprises, after the third etching process and before the fourth etching process, filling a first portion of the second opening formed by the third etching process with a first part of the conductive material; and after the fourth etching process, filling a second portion of the second opening formed by the fourth etching process with a second part of the conductive material. In an embodiment, the dielectric region penetrates through, and contacts sidewalls of some remaining portions of, stacked layers, and wherein the stacked layers comprise a plurality of semiconductor layers formed of a first material; and a plurality of dielectric inner spacers, wherein the plurality of semiconductor layers and the plurality of dielectric inner spacers are located alternatingly.

In an embodiment, the dielectric region comprises a first sidewall physically contacting a second sidewall of a source/drain region of one of the first lower transistor and the first upper transistor. In an embodiment, the first lower transistor and the first upper transistor are formed through a monolithic formation process. In an embodiment, the first lower transistor and the first upper transistor are formed by processes comprising forming the first lower transistor in a first wafer; forming the first upper transistor in a second wafer; and bonding the first wafer to the second wafer, wherein the first etching process is performed after the bonding. In an embodiment, the first upper transistor is formed after the first lower transistor has been formed, and the dielectric region is formed after the first upper transistor is formed.

In accordance with some embodiments of the present disclosure, a structure comprises a first CFET comprising a first lower transistor; and a first upper transistor overlapping the first lower transistor; a second CFET comprising a second lower transistor; and a second upper transistor overlapping the second lower transistor; a dielectric liner in middle between the first CFET and the second CFET, the dielectric liner comprising an upper portion between the first upper transistor and the second upper transistor; and a lower portion between the first lower transistor and the second lower transistor; a through-via encircled by the dielectric liner; a first contact plug overlying and connecting to the through-via; and a second contact plug underlying and connecting to the through-via.

In an embodiment, the structure further comprises a plurality of semiconductor layers; and a plurality of inner spacers separating the plurality of semiconductor layers, wherein the dielectric liner contacts sidewalls of each of the plurality of semiconductor layers and the plurality of inner spacers. In an embodiment, one of the first lower transistor and the first upper transistor comprises a source/drain region, and the source/drain region physically contacts a sidewall of the dielectric liner. In an embodiment, from top to bottom of the dielectric liner, the dielectric liner is increasingly thinner. In an embodiment, in a middle part of the dielectric liner, the dielectric liner has an abrupt change in thicknesses.

In accordance with some embodiments of the present disclosure, a structure comprises a CFET comprising a lower transistor comprising a first gate stack; and a first gate spacer on a sidewall of the first gate stack; and an upper transistor overlapping the lower transistor and comprising a second gate stack; and a second gate spacer on a sidewall of the second gate stack; a dielectric liner comprising an upper portion contacting a first sidewall of the second gate spacer; and a lower portion contacting a second sidewall of the first gate spacer; and a through-via encircled by the dielectric liner. In an embodiment, the structure further comprises an additional CFET comprising an additional gate spacer, wherein the dielectric liner is further in physical contact with an additional sidewall of the additional gate spacer. In an embodiment, a middle portion of the dielectric liner has abruptly changed thicknesses.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first complementary Field-Effect Transistor (CFET) comprising:
a first lower transistor; and
a first upper transistor overlapping the first lower transistor;
forming a second CFET comprising:
a second lower transistor; and
a second upper transistor overlapping the second lower transistor;
performing a first etching process to form a first opening, wherein the first etching process comprises:
etching a gate stack between the first CFET and the second CFET; and
etching a plurality of alternating structures vertically aligned to the gate stack;
filling the first opening with a dielectric material to form a dielectric region;
performing a second etching process to etch a middle portion of the dielectric region and to form a second opening; and
filling the second opening with a conductive material to form a through-via;
forming a first contact plug overlying the through-via; and
forming a second contact plug underlying the through-via, wherein the first contact plug is electrically connected to the second contact plug through the through-via, and wherein at a time after the second etching process, a remaining portion of the dielectric region encircles the second opening.
